(19) United States
(12) Patent Application Publication
(10) Pub. No.: US 2025/0098503 A1
(43) Pub. Date: Mar. 20, 2025

(54) Display Panel and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Yanyang Shang, Beijing (CN); Shuo Li, Beijing (CN); Zhenglong Yan, Beijing (CN)

(21) Appl. No.: 18/727,315

(22) PCT Filed: Aug. 30, 2022
(86) PCT No.: PCT/CN2022/115865

§ 371 Date: Jul. 8, 2024

(51) Int. Cl. H10K 59/80; H10K 59/40

(52) U.S. Cl. CPC H10K 59/8792; H10K 59/40

(57) ABSTRACT

A display panel includes a display structure, a touch layer located on a light-exit side of the display substrate, and a black matrix layer located on a side of the layer away from the display substrate. The display substrate includes sub-pixels each having a light-emitting region located within a reference region. The touch layer includes a metal mesh structure including metal lines. Orthogonal projections of the metal lines on the display substrate are located between reference regions where light-emitting regions of the sub-pixels are located. A spacing exists between a metal line adjacent to the light-emitting region of the sub-pixel and the reference region where the light-emitting region is located. The black matrix layer includes openings. An orthogonal projection of each opening on the display substrate surrounds a single light-emitting region and is at least partially located outside a reference region where the single light-emitting region is located.

### CROSS-REFERENCE TO RELATED APPLICATION

This application is the United States national phase of International Patent Application No. PCT/CN2022/115865, filed Aug. 30, 2022, the disclosure of which is hereby incorporated by reference in its entirety.

### BACKGROUND OF THE INVENTION

### Field of the Invention

The present disclosure relates to the field of display technologies, and in particular, to a display panel and a display apparatus.

### Description of Related Art

Organic light-emitting diode (OLED) display panels have attracted much attention due to their advantages of self-illumination, wide viewing angle, high contrast, fast response, low power consumption, etc.

Through a flexible multi-layer on cell (FMLOC) and a color filter on encapsulation (COE), a touch layer (touch structure) and a color filter are integrated to form a display panel of a stacked structure of multi-functional layers. Therefore, a thickness of the display apparatus is reduced, which facilitates the lightness and thinness of the display apparatus.

### SUMMARY OF THE INVENTION

In an aspect, a display panel is provided. The display panel includes a display substrate, a touch layer and a black matrix layer. The display substrate includes a plurality of sub-pixels, each sub-pixel has a light-emitting region, and the light-emitting region is located in a reference region. A shape of the reference region is a closed figure enclosed by at least one straight edge and at least one arc edge. The touch layer is located on a light-exit side of the display substrate. The touch layer includes a metal mesh structure, and the metal mesh structure includes a plurality of metal lines. Orthogonal projections of the plurality of metal lines on the display substrate are located between reference regions where light-emitting regions of the plurality of sub-pixels are located; and a spacing exists between a metal line adjacent to the light-emitting region of the sub-pixel and the reference region where the light-emitting region is located. The black matrix layer is located on a side of the touch layer away from the display substrate and includes a plurality of openings. An orthogonal projection of each opening on the display substrate surrounds a single light-emitting region and is at least partially located outside a reference region where the light-emitting region is located.

In some embodiments, the plurality of sub-pixels include a plurality of first sub-pixels, each first sub-pixel has a first light-emitting region, and each first light-emitting region is located within a first reference region; the plurality of openings include a plurality of first openings, an orthogonal projection of each first opening on the display substrate surrounds a single first light-emitting region, and a shape of the first opening is substantially the same as a shape of the first light-emitting region surrounded by the first opening.

In some embodiments, the plurality of sub-pixels include a plurality of first sub-pixels, each first sub-pixel has a first light-emitting region, and each first light-emitting region is located within a first reference region; the plurality of openings include a plurality of first openings, and an orthogonal projection of each first opening on the display substrate surrounds a single first reference region; a boundary of the first opening and a boundary of a first light-emitting region surrounded by the first opening have a spacing therebetween, and a shape of the first opening is the same as a shape of the first reference region surrounded by the first opening.

In some embodiments, the first opening is substantially in a shape of a rhombus and includes four first borders connected end to end, and the first borders are substantially straight lines; a diagonal line of the first opening extends substantially in a first direction, and another diagonal line of the first opening extends substantially in a second direction; the first direction is a row direction in which the plurality of sub-pixels are arranged, and the second direction is a column direction in which the plurality of sub-pixels are arranged.

In some embodiments, the metal mesh structure includes a plurality of first meshes, a first mesh is substantially in a shape of a hexagon and includes two first extension sections that are oppositely arranged and extend in the first direction and four second extension sections; in a case where the first opening is substantially in a shape of a rhombus, the four second extension sections are substantially parallel to the four first borders, respectively. An orthogonal projection of each first mesh on the display substrate surrounds an orthogonal projection of a first opening on the display substrate.

In some embodiments, the plurality of first sub-pixels are arranged in rows and columns. In the first direction, first meshes are connected to form a first mesh row; and in the second direction, a spacing exists between two adjacent first mesh rows.

In some embodiments, the shape of the first light-emitting region is substantially a circle or a rhombus.

In some embodiments, in a case where the shape of the first light-emitting region is substantially a circle, a boundary of the first light-emitting region has a distance from the first reference region, or is tangent to the first reference region; in a case where the shape of the first light-emitting region is substantially a rhombus, the boundary of the first light-emitting region substantially coincides with a boundary of the first reference region.

In some embodiments, the plurality of sub-pixels further include a plurality of second sub-pixels, each second sub-pixel has a second light-emitting region, and each second light-emitting region is located within a second reference region; the plurality of openings include a plurality of second openings, an orthogonal projection of each second opening on the display substrate surrounds a single second light-emitting region, and a shape of the second opening is the same as a shape of the second light-emitting region surrounded by the second opening.

In some embodiments, the plurality of sub-pixels further include a plurality of second sub-pixels, each second sub-pixel has a second light-emitting region, and each second light-emitting region is located within a second reference region; the plurality of openings include a plurality of second openings, and an orthogonal projection of each second opening on the display substrate surrounds a single second reference region; a boundary of the second opening and a boundary of a second light-emitting region surrounded by the second opening have a spacing therebetween, and a shape of the second opening is the same as a shape of the second reference region surrounded by the second opening.

In some embodiments, the second opening is substantially in a shape of a rhombus and includes four second borders connected end to end, and the second borders are substantially straight lines; a diagonal line of the second opening extends substantially in a first direction, and another diagonal line of the second opening extends substantially in a second direction. In a case where the plurality of sub-pixels further include a plurality of first sub-pixels, an area of the second light-emitting region is greater than an area of a first light-emitting region, and an area of the second opening is greater than an area of a first opening.

In some embodiments, the metal mesh structure further includes a plurality of second meshes, an orthogonal projection of each second mesh on the display substrate surrounds a single second opening, and the second mesh includes four third extension sections; in a case where the second opening is substantially in a shape of a rhombus, the four third extension sections are substantially parallel to the four second borders, respectively.

In some embodiments, the black matrix layer further includes a plurality of light-transmitting holes; two sides of the second opening in a first direction are each provided with one light-transmitting hole, and the light-transmitting hole is located between two adjacent first openings in a second direction; an orthogonal projection of the second mesh on the display substrate further surrounds orthogonal projections, on the display substrate, of two light-transmitting holes on the two sides of the second opening in the first direction; the second mesh further includes four fourth extension sections extending in the first direction and two fifth extension sections extending in the second direction; each two fourth extension sections constitute a group and are respectively located on two sides of a light-transmitting hole in the second direction; an end of a fourth extension section close to the second opening is connected to a single third extension section; and a fifth extension section is connected to two ends, away from the second opening, of two fourth extension sections in a group.

In some embodiments, in a case where the metal mesh structure includes a plurality of first meshes, an extension section of a first mesh and an extension section of a second mesh that are adjacent to each other share a metal line.

In some embodiments, the shape of the second light-emitting region is substantially a circle, a quasi-ellipse, a rhombus or a diamond; the quasi-ellipse includes a first curved edge and a second curved edge, two ends of the first curved edge are respectively connected to two ends of the second curved edge, and a line connecting two connection points of the first curved edge and the second curved edge is a first line segment; the first curved edge and the first line segment enclose a semi-ellipse, and the second curved edge and the first line segment enclose a semicircle; the diamond includes a first straight edge, a second straight edge and a third curved edge, the first straight edge and the second straight edge are connected to form a first polyline-shaped edge, and two ends of the third curved edge are respectively connected to two ends of the first polyline-shaped edge; the third curved edge includes a first straight line segment, a curved line segment and a second straight line segment connected in sequence; and the first straight line segment is connected to the first straight edge, and the second straight line segment is connected to the second straight edge.

In some embodiments, in a case where the shape of the second light-emitting region is substantially a circle, a boundary of the second light-emitting region has a distance from the second reference region, or is tangent to the second reference region; in a case where the shape of the second light-emitting region is substantially a quasi-ellipse, a border of the second light-emitting region formed by the first curved edge has a distance from the second reference region, and a border of the second light-emitting region formed by the second edge is tangent to the boundary of the second reference region; in a case where the shape of the second light-emitting region is substantially a rhombus, the boundary of the second light-emitting region substantially coincides with the boundary of the second reference region; in a case where the shape of the second light-emitting region is substantially a diamond, borders of the second light-emitting region formed by the first straight edge, the second straight edge, and the first straight line segment and the second straight line segment of the third curved edge coincide with part of the boundary of the second reference region, and a border of the second light-emitting region formed by the curved line segment of the third curved edge has a distance from the boundary of the second reference region.

In some embodiments, the plurality of sub-pixels further include a plurality of third sub-pixels, a third sub-pixel has a third light-emitting region, and each third light-emitting region is located in a third reference region; the plurality of openings include a plurality of third openings, an orthogonal projection of each third opening on the display substrate surrounds a single third light-emitting region, and a shape of the third opening is the same as a shape of the third light-emitting region surrounded by the third opening.

In some embodiments, the plurality of sub-pixels further include a plurality of third sub-pixels, a third sub-pixel has a third light-emitting region, and each third light-emitting region is located in a third reference region; the plurality of openings include a plurality of third openings, and an orthogonal projection of each third opening on the display substrate surrounds a single third reference region; a boundary of the third opening and a boundary of a third light-emitting region surrounded by the third opening have a spacing therebetween, and a shape of the third opening is the same as a shape of the third reference region surrounded by the third opening.

In some embodiments, the third opening includes one arc border, two third borders and two fourth borders; the two third borders and the two fourth borders are substantially straight lines; two ends of the arc border are each connected to an end of a single third border; another end of the third border is connected to a single fourth border; another ends of the two fourth borders are connected to each other; the third opening has a first symmetry axis, and the first symmetry axis passes through a midpoint of the arc border and a connection point of the two fourth borders.

In some embodiments, the metal mesh structure further includes a plurality of third meshes; the third meshes are substantially hexagonal, and each include two sixth extension sections, two seventh extension sections and two eighth extension sections; and an orthogonal projection of each third mesh on the display substrate surrounds a single third opening whose first symmetry axis extends in the second direction.

In some embodiments, in a case where the metal mesh structure includes a plurality of first meshes and a plurality of second meshes, an extension section of the third mesh and an extension section of a first mesh that are adjacent share a metal line, and an extension section of the third mesh and an extension section of a second mesh that are adjacent share a metal line.

In some embodiments, the plurality of third sub-pixels are arranged in rows and columns; in a case where the plurality of sub-pixels further include a plurality of second sub-pixels, third sub-pixels and second sub-pixels are alternately arranged in a first direction; and third meshes and second meshes are alternately arranged in the first direction.

The metal mesh structure further includes a plurality of fourth meshes; a fourth mesh includes two polyline-shaped extension sections that are oppositely arranged and two ninth extension sections extending in a second direction; a polyline-shaped extension section includes three V-shaped sub-sections that are spaced apart in a first direction and two straight sub-sections that are each connected to two adjacent V-shaped sub-sections; V-shaped sub-sections of the two polyline-shaped extension sections protrude in directions away from each other; a ninth extension section extends in the second direction and connects ends of the two polyline-shaped extension sections.

An orthogonal projection of each fourth mesh on the display substrate surrounds orthogonal projections, on the display substrate, of two adjacent third openings in the first direction and one second opening located between the two third openings.

In some embodiments, in a case where the metal mesh structure further includes a plurality of first meshes and a plurality of second meshes, an extension section of the fourth mesh and an extension section of a first mesh that are adjacent share a metal line, and an extension section of the fourth mesh and an extension section of a second mesh that are adjacent share a metal line.

In some embodiments, the plurality of third sub-pixels are arranged in rows and columns; in a case where the plurality of sub-pixels further include a plurality of second sub-pixels, third sub-pixels and second sub-pixels are alternately arranged in the first direction, and fourth meshes and second meshes are alternately arranged in the first direction.

In some embodiments, the plurality of third sub-pixels are arranged in rows and columns, and the plurality of third openings are arranged in rows and columns; in a case where the shape of the third opening is the same as the shape of the third reference region, first symmetry axes of third openings in the same row are parallel to each other, and first symmetry axes of third openings in two adjacent rows are perpendicular to each other.

In some embodiments, the metal mesh structure includes a plurality of first meshes, a plurality of second meshes, a plurality of third meshes and a plurality of fourth meshes, third meshes and second meshes are alternately arranged in the first direction to form a second mesh row, and fourth meshes and second meshes are alternately arranged in the first direction to form a third mesh row. First meshes are arranged in the first direction to form a first mesh row. Third meshes and second meshes alternately arranged in the first direction form a second mesh row, and fourth meshes and second meshes alternately arranged in the first direction form a third mesh row; in a second direction, second mesh rows and third mesh rows are alternately arranged, and a first mesh row is arranged between a second mesh row and a third mesh row that are adjacent.

In some embodiments, the shape of the third light-emitting region is substantially a circle, a quasi-ellipse, a rhombus or a diamond.

In some embodiments, the third reference region includes one virtual arc edge, two third virtual straight edges and two fourth virtual straight edges; the two third virtual straight edges and the two fourth virtual straight edges are substantially straight lines; two ends of the virtual arc edge are each connected to an end of a single third virtual straight edge; another end of the third virtual straight edge is connected to a single fourth virtual straight edge; another ends of the two fourth virtual straight edges are connected to each other.

In a case where the shape of the third light-emitting region is substantially a circle, the boundary of the third light-emitting region is located in the third reference region and is tangent to the two fourth virtual straight edges of the third reference region; or, part of the boundary of the third light-emitting region coincides with the virtual arc edge of the third reference region, and part of the boundary is located within the third reference region and has a distance from the boundary of the third reference region.

In a case where the shape of the third light-emitting region is substantially a quasi-ellipse, the third light-emitting region is located within the third reference region.

In a case where the shape of the third light-emitting region is substantially a rhombus, part of the boundary of the third light-emitting region coincides with the two third virtual straight edges and the two fourth virtual straight edges, and part of the boundary of the third light-emitting region is located within the third reference region.

In a case where the shape of the third light-emitting region is substantially a diamond, borders of the third light-emitting region formed by a first straight edge, a second straight edge, a first straight line segment and a second straight line segment of the diamond coincide with the two third virtual straight edges and the two fourth virtual straight edges, and a border of the third light-emitting region formed by a third curved edge of the diamond is located within the third reference region.

In some embodiments, the touch layer includes a first metal layer, a second metal layer, and an insulating layer located between the first metal layer and the second metal layer, the insulating layer being provided therein with a plurality of via holes; one of the first metal layer and the second metal layer includes a plurality of first touch electrodes, a plurality of second touch electrodes and a plurality of connection portions, and another of the first metal layer and the second metal layer includes a plurality of bridge portions; each connection portion connects two adjacent first touch electrodes, and each bridge portion connects two adjacent second touch electrodes through via holes; or, each connection portion connects two adjacent second touch electrodes, and each bridge portion connects two adjacent first touch electrodes through via holes; and at least one of a first touch electrode, a second touch electrode, a connection portion and a bridge portion includes a part of the metal mesh structure.

In some embodiments, the display panel further includes a color filter layer. The color filter layer includes a plurality of filter portions, and at least part of each filter portion is located in an opening. In a case where the plurality of openings include a plurality of first openings, a plurality of second openings and a plurality of third openings, the plurality of filter portions include a plurality of first color filter portions, a plurality of second color filter portions and a plurality of third color filter portions; at least part of each first color filter portion is located in a first opening, at least part of each second color filter portion is located in a second opening, and at least part of each third color filter portion is located in a third opening.

In some embodiments, a spacing between an orthogonal projection of a boundary of the opening on the display substrate and a boundary of a reference region surrounded by the opening is D1; a spacing between the orthogonal projection of the boundary of the opening on the display substrate and a boundary of an orthogonal projection of a metal line on the display substrate is D2; a line width of the metal line is D3; a spacing between boundaries of light-emitting regions of two adjacent sub-pixels is D4; and D3=D4−2×D1−2×D2.

In some embodiments, the spacing D1 between the orthogonal projection of the boundary of the opening on the display substrate and the boundary of a reference region surrounded by the opening is greater than or equal to 2.5 μm. And/or, the spacing D2 between the orthogonal projection of the boundary of the opening on the display substrate and the boundary of the orthogonal projection of the metal line on the display substrate is greater than or equal to 4 μm. And/or, the line width D3 of the metal line is greater than or equal to 3 μm. And/or, the spacing D4 between the boundaries of the light-emitting regions of the two adjacent sub-pixels is greater than or equal to 17 μm.

In some embodiments, the black matrix further includes a plurality of light-transmitting holes. A spacing D5 between an orthogonal projection of a boundary of each light-transmitting hole on the display substrate and an orthogonal projection of an adjacent metal line on the display substrate is substantially equal to D2.

In another aspect, a display apparatus is provided. The display apparatus includes the display panel as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a display panel, in accordance with some embodiments;

FIG. 3 is a structural diagram of a display substrate, in accordance with some embodiments;

FIG. 4 is a sectional view showing a structure of a display panel, in accordance with some embodiments;

FIG. 5 is a structural diagram of light-emitting regions of a display substrate, in accordance with some embodiments;

FIG. 6A is a plan view showing a structure of a touch layer, in accordance with some embodiments;

FIG. 6B is a sectional view taken along the section line A-A in FIG. 6A;

FIG. 7 is a structural diagram of a display substrate and a metal mesh structure, in accordance with some embodiments;

FIG. 8A is a structural diagram of a display panel, in accordance with some embodiments;

FIG. 8B is a structural diagram of another display panel, in accordance with some embodiments;

FIG. 9 is a structural diagram of a color filter structure, in accordance with some embodiments;

FIG. 10A is a structural diagram of a display substrate, in accordance with some embodiments;

FIG. 10B is a structural diagram of another display substrate, in accordance with some embodiments;

FIG. 10C is a structural diagram of yet another display substrate, in accordance with some embodiments;

FIG. 10D is a structural diagram of yet another display substrate, in accordance with some embodiments;

FIG. 10E is a structural diagram of yet another display substrate, in accordance with some embodiments;

FIG. 11 is a structural diagram of reference regions, in accordance with some embodiments;

FIG. 12 is a structural diagram of a wiring space for a metal line, in accordance with some embodiments;

FIG. 13 is a structural diagram of a metal mesh structure and a black matrix layer, in accordance with some embodiments;

FIG. 14 is a structural diagram of a black matrix layer, in accordance with some embodiments;

FIG. 15 is a structural diagram of a metal mesh structure, in accordance with some embodiments;

FIG. 16 is a structural diagram of another metal mesh structure, in accordance with some embodiments;

FIG. 17A is a structural diagram of a display panel, in accordance with some embodiments;

FIG. 17B is a structural diagram of another display panel, in accordance with some embodiments;

FIG. 17C is a structural diagram of yet another display panel, in accordance with some embodiments;

FIG. 17D is a structural diagram of yet another display panel, in accordance with some embodiments;

FIG. 17E is a structural diagram of yet another display panel, in accordance with some embodiments;

FIG. 18A is a structural diagram of yet another display panel, in accordance with some embodiments;

FIG. 18B is a structural diagram of yet another display panel, in accordance with some embodiments;

FIG. 18C is a structural diagram of yet another display panel, in accordance with some embodiments;

FIG. 18D is a structural diagram of yet another display panel, in accordance with some embodiments; and

FIG. 18E is a structural diagram of yet another display panel, in accordance with some embodiments.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms such as “first” and “second” are only used for descriptive purposes and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled,” “connected,” and derivatives thereof may be used. For example, the term “connected” may be used in the description of some embodiments to indicate that two or more elements are in direct physical or electrical contact with each other. As another example, the term “coupled” may be used in the description of some embodiments to indicate that two or more elements are in direct physical or electrical contact with each other.

The phrase “A and/or B” includes following three combinations: only A, only B, and a combination of A and B.

The phrase “configured to” used herein means an open and inclusive expression, which does not exclude devices that are applicable to or configured to perform additional tasks or steps.

In addition, the phrase “based on” used herein is meant to be open and inclusive, since a process, step, calculation or other action that is “based on” one or more of the stated conditions or values may, in practice, be based on additional conditions or values exceeding those stated.

The term such as “about,” “substantially,” and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views that are schematic illustrations of idealized embodiments. In the accompanying drawings, thicknesses of layers and sizes of regions may be exaggerated for clarity. Therefore, variations in shape with respect to the drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of the regions in a device, and are not intended to limit the scope of the exemplary embodiments.

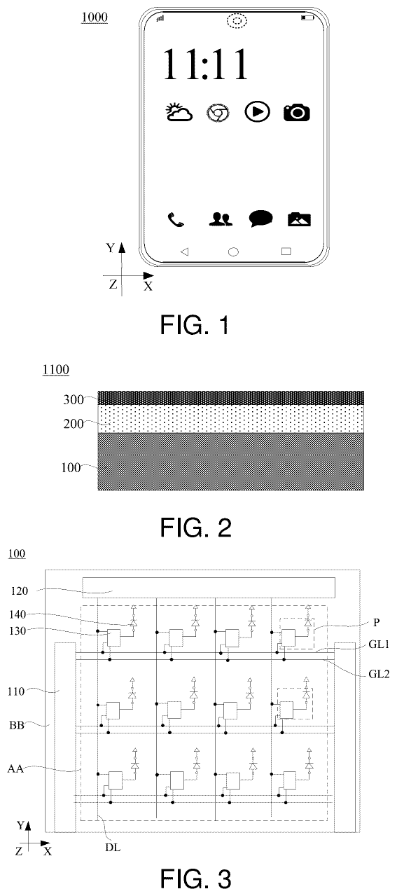

Some embodiments of the present disclosure provide a display apparatus 1000. Referring to FIG. 1, the display apparatus 1000 may be any apparatus that displays an image whether in motion (e.g., a video) or stationary (e.g., a still image), and whether textual or graphical. For example, the display apparatus 1000 may be any product or component having a display function, such as a television, a notebook computer, a tablet computer, a mobile phone, an electronic photo, an electronic billboard or indicator, a personal digital assistant (PDA), a navigator, a wearable device, an augmented reality (AR) device, or a virtual reality (VR) device.

The display apparatus 1000 may be an electroluminescent display apparatus or a photoluminescent display apparatus. In a case where the display apparatus is an electroluminescent display apparatus, the electroluminescent display apparatus is an organic electroluminescent display apparatus (e.g., an organic light-emitting diode (OLED) display apparatus) or a quantum dot electroluminescent display apparatus (e.g., a quantum dot light-emitting diode (QLED) display apparatus). In a case where the display apparatus 1000 is a photoluminescent display apparatus, the photoluminescent display apparatus is a quantum dot photoluminescent display apparatus.

In some embodiments, referring to FIG. 2, the display apparatus 1000 includes a display panel 1100, and the display panel 1100 may include a display substrate 100, a touch layer 200 and a color filter structure 300 that are stacked. The display substrate 100 has a light-exit surface (e.g., an upper surface of the display substrate 100 in FIG. 2). The light-exit surface refers to a surface of the display substrate used for displaying image information. The touch layer 200 is disposed on a side close to the light-exit surface of the display substrate 100. The color filter structure 300 is disposed on a side of the touch layer 200 away from the display substrate 100.

For example, referring to FIG. 3, the display substrate 100 includes a display region AA and a periphery region (also called non-display region) BB disposed on at least one side of the display region AA. In the embodiments of the present disclosure, FIG. 3 illustrates an example in which the peripheral region BB surrounds the display region AA. The peripheral region BB may include at least a gate driving circuit 110 and a data driving circuit 120.

The display region AA may include at least a plurality of sub-pixels P, a plurality of data lines DL, a plurality of first gate lines GL1, and a plurality of second gate lines GL2.

The plurality of sub-pixels P are arranged in multiple rows and multiple columns. Each row includes multiple sub-pixels P arranged in a first direction X. That is, the first direction X is a row direction in which the plurality of sub-pixels P are arranged, and the multiple rows are arranged in a second direction Y. Each column includes multiple sub-pixels P arranged in the second direction Y. That is, the second direction Y is a column direction in which the plurality of sub-pixels P are arranged, and the multiple columns are arranged in the first direction X. The first direction X and the second direction Y intersect. For example, the first direction X is perpendicular to the second direction Y.

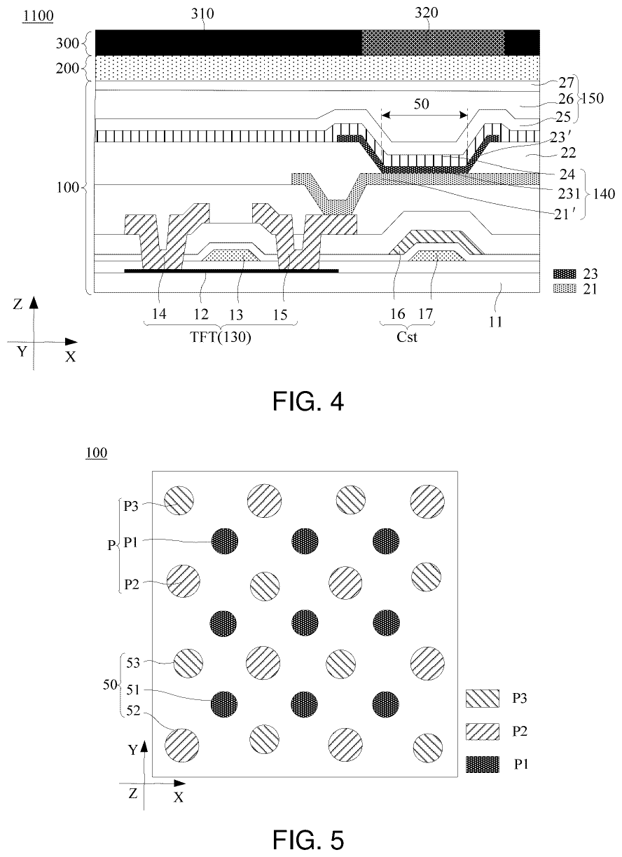

Referring to FIGS. 3 and 4, the sub-pixel P is the smallest light-emitting unit of the display substrate 100. The sub-pixel P includes a pixel circuit 130 and a light-emitting device 140.

As shown in FIG. 3, multiple pixel circuits 130 of the plurality of sub-pixels P are electrically connected to the data driving circuit 120 located in the peripheral region BB through the plurality of data lines DL. For example, a plurality of pixel circuits 130 of each column of sub-pixels P are electrically connected to the data driving circuit 120 through at least one data line DL.

The plurality of pixel circuits 130 of the plurality of sub-pixels P are electrically connected to the gate driving circuit 110 through the plurality of first gate lines GL1 and the plurality of second gate lines GL2. For example, multiple pixel circuits 130 of each row of sub-pixels P are electrically connected to the gate driving circuit 110 through one first gate line GL1 and one second gate line GL2.

In some embodiments, the pixel circuit 130 includes a plurality of switching devices and at least one capacitor Cst.

For example, the switching devices may be thin film transistors (TFTs) or field effect transistors (FETs). The embodiments of the present disclosure are described by taking an example where the switching devices are TFTs. That is, the pixel circuit 130 includes a plurality of TFTs.

The TFT may be a P-type transistor or an N-type transistor. The P-type transistor is turned on due to a low potential and is turned off due to a high potential. The N-type transistor is turned on due to a high potential and is turned off due to a low potential.

For example, the pixel circuit 130 may be a “3T1C” circuit, a “7T1C” circuit or an “8T2C” circuit, where “T” refers to a TFT, the number preceding “T” refers to the number of TFTs, “C” is refers to a capacitor Cst, and the number preceding “C” refers to the number of capacitors Cst. The embodiments of the present disclosure do not limit the specific structure of the pixel circuit 130.

For example, as shown in FIG. 4, the display substrate 100 includes a substrate 11. The TFT may include an active layer 12, a gate 13, a source 14 and a drain 15 disposed on the substrate 11. The source 14 and the drain 15 are located in the same film layer. That is, the source 14 and the drain 15 are formed simultaneously through the same film forming process. In addition, the source 14 and the drain 15 may be symmetrical in structure. That is, the source 14 and the drain 15 may be the same in structure. The capacitor may include a first electrode plate 16 and a second electrode plate 17. It can be understood that in a third direction Z (a direction perpendicular to the substrate 11), every two adjacent conductive layers are provided with at least one insulating layer therebetween (which will not be described in the embodiments of the present disclosure).

The display substrate 100 further includes an anode layer 21, a pixel definition layer 22, a light-emitting functional layer 23, and a cathode layer 24 that are disposed on a side of the pixel circuits 130 away from the substrate 11. The anode layer 21 includes a plurality of anodes 21′ separated from each other (FIG. 4 illustrates only one anode 21′). The pixel definition layer 22 is provided therein with a plurality of fourth openings 22′. Each fourth opening 22′ exposes at least part of an anode 21′ and defines a light-emitting region 50 of a sub-pixel P. The light-emitting functional layer 23 includes a plurality of light-emitting functional patterns 23′ (FIG. 4 illustrates only one light-emitting functional pattern 23′). At least part of each light-emitting functional pattern 23′ is located in a fourth opening 22′. The cathode layer 24 is of a one-piece structure. Each anode 21′, a light-emitting functional pattern 23′ located on the anode 21′, and a portion of the cathode 24 directly opposite to the anode 21′ together constitute a light-emitting device 140.

Referring to FIG. 4, the display substrate 100 further includes an encapsulation layer 150 disposed on a side of the cathode layer 24 away from the substrate 11. For example, the encapsulation layer 150 may include a first inorganic material layer 25, an organic material layer 26, and a second inorganic material layer 27 that are sequentially stacked in the third direction Z and a direction away from the substrate 11 (a direction from bottom to top in FIG. 4). The first inorganic material layer 25 and the second inorganic material layer 27 can isolate water and oxygen, thereby reducing a risk of external water and oxygen eroding the film structures below the encapsulation layer 150, especially reducing a risk of water and oxygen eroding the light-emitting functional layers 23, and improving the service life of the display substrate 100. The organic material layer 26 may be used to planarize the light-exit surface of the display substrate 100, and to absorb and release stress of the display substrate 100.

Referring to FIG. 5, the plurality of sub-pixels P include a plurality of first sub-pixels P1, a plurality of second sub-pixels P2 and a plurality of third sub-pixels P3. Each sub-pixel P has a light-emitting region 50. FIG. 5 is a plan view of a display substrate 100. A shape of the sub-pixel P is a shape of the light-emitting region 50 corresponding to the sub-pixel P. That is to say, blocky patterns shown in FIG. 5 are patterns of light-emitting regions 50 of multiple sub-pixels P.

In the case where the plurality of sub-pixels P include a plurality of first sub-pixels P1, a plurality of second sub-pixels P2 and a plurality of third sub-pixels P3, each first sub-pixel P1 has a first light-emitting region 51, each second sub-pixel P2 has a second light-emitting region 52, and each third sub-pixel P3 has a third light-emitting region 53. That is, the plurality of light-emitting regions 50 include a plurality of first light-emitting regions 51, a plurality of second light-emitting regions 52 and a plurality of third light-emitting regions 53.

Shapes of light-emitting regions 50 (a first light-emitting region 51, a second light-emitting region 52 and a third light-emitting region 53) corresponding to different sub-pixels (a first sub-pixel P1, a second sub-pixel P2 and a third sub-pixel P3) may be the same or different, and aperture ratios of the light-emitting regions 50 corresponding to different sub-pixels P may also be the same or different.

As shown in FIG. 4, the touch layer 200 is disposed on a light-exit side of the display substrate 100, i.e., on a side of the encapsulation layer 150 away from the substrate.

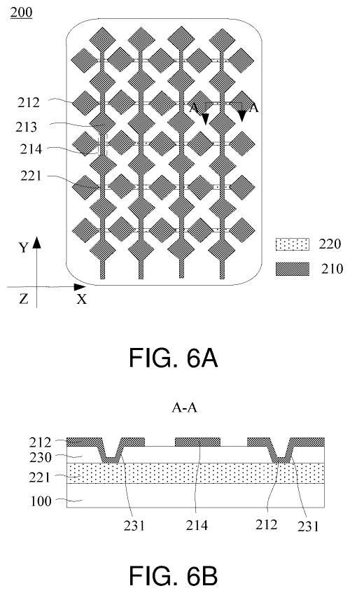

Referring to FIGS. 6A and 6B, the touch layer 200 may include a first metal layer 210, a second metal layer 220, and an insulating layer 230 between the first metal layer 210 and the second metal layer 220. For example, the first metal layer 210 is farther away from the display substrate 100 than the second metal layer 220.

One of the first metal layer 210 and the second metal layer 220 includes a plurality of first touch electrodes 212, a plurality of second touch electrodes 213 and a plurality of connection portions 214. Another of the first metal layer 210 and the second metal layer 220 includes a plurality of bridge portions 221. The insulating layer 230 is provided therein with a plurality of via holes 231.

For example, referring to FIG. 6A, the first metal layer 210 includes the plurality of first touch electrodes 212, the plurality of second touch electrodes 213 and the plurality of connection portions 214; and the second metal layer 220 includes the plurality of bridge portions 221.

Each connection portion 214 connects two first touch electrodes 212 that are adjacent (in the second direction Y), and each bridge portion 221 connects two adjacent second touch electrodes 213 through via holes 231 (as shown in FIGS. 6A and 6B). Alternatively, each connection portion connects two adjacent second touch electrodes, and each bridge portion connects two adjacent first touch electrodes through via holes (not shown in the figures).

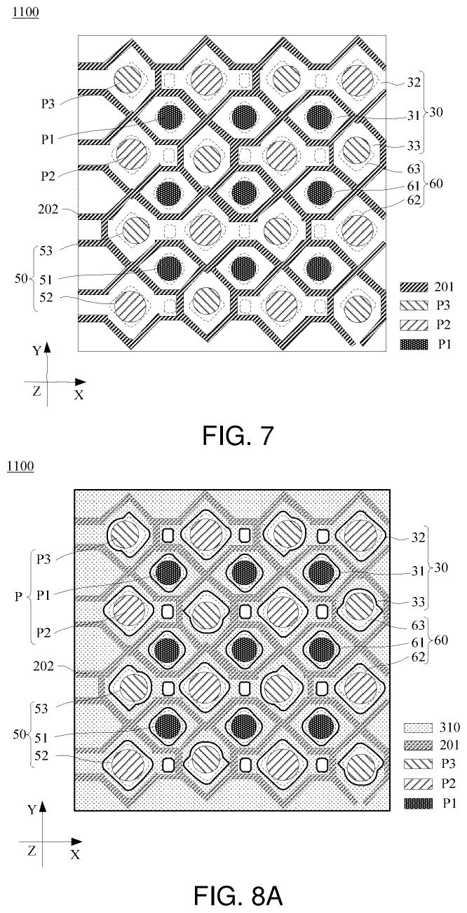

Referring to FIGS. 6A and 7, the touch layer 200 includes a metal mesh structure 201, and at least one of the first touch electrode 212, the second touch electrode 213, the connection portion 214 and the bridge portion 221 includes a part of the metal mesh structure 201. For example, the first touch electrode 212, the second touch electrode 213, the connection portion 214 and the bridge portion 221 each include a part of the metal mesh structure 201. FIG. 7 is a structural diagram of the display substrate 100 in FIG. 5 with a part of the metal mesh structure 201. Of course, it can also be understood that FIG. 7 may also be regarded as a partial enlarged view of one of the first touch electrode 212, the second touch electrode 213, the connection portion 214 and the bridge portion 221.

The metal mesh structure 201 includes a plurality of metal lines 202. Orthogonal projection of the plurality of metal lines 202 on the display substrate 100 are located between the light-emitting regions 50 of the plurality of sub-pixels P, and each have a spacing from an adjacent light-emitting region 50. In this way, it may be possible to reduce light emitted by the sub-pixel P being blocked by the metal line 202, reduce the influence of the touch layer 200 on the light extraction efficiency of the display panel 1100, and improve the light extraction efficiency of the display panel 1100.

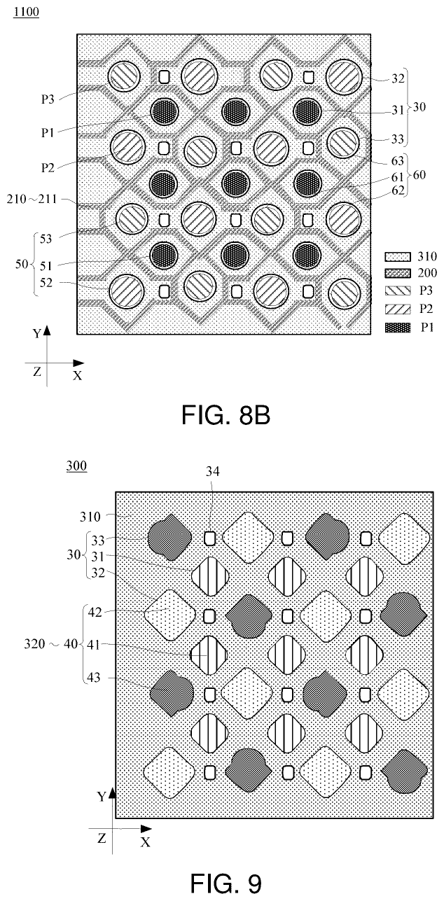

As shown in FIG. 4, the color filter structure 300 is disposed on a side of the touch layer 200 away from the display substrate 100. Referring to FIGS. 8A, 8B and 9, the color filter structure 300 may include a black matrix layer 310 and a color filter layer 320. The black matrix layer 310 is made of a photoresist material. That is, the black matrix layer 310 is made of an opaque material or a material with very low light transmittance. In this way, the black matrix layer 310 may reduce the reflection of ambient light by the display panel 1100. The black matrix 310 is provided therein with a plurality of openings 30. An orthogonal projection of each opening 30 on the display substrate 100 surrounds (or covers) a light-emitting region 50 of a sub-pixel P, and is at least partially located outside a reference region 60 where the light-emitting region 50 (surrounded by the opening) is located. Compared with FIG. 7, in FIG. 8A, a black matrix layer 310 is added on the display substrate 100 and the touch layer 200. FIG. 9 is a structural diagram of the color filter structure 300.

It can be understood that the orthogonal projection of each opening 30 on the display substrate 100 may surround a light-emitting region 50 or a reference region 60 where the light-emitting region 50 is located (reference is made to the description below). In the case where the orthogonal projection of each opening 30 on the display substrate 100 surrounds a light-emitting region 50, the orthogonal projection of the opening 30 on the display substrate 100 is partially located outside the reference region 60. In the case where the orthogonal projection of each opening 30 on the display substrate 100 surrounds a reference region 60, the orthogonal projection of the opening 30 on the display substrate 100 is entirely located outside the reference region 60. The orthogonal projection of the opening 30 on the display substrate 100 can be understood as an orthogonal projection of a boundary of the opening 30 on the display substrate 100; in this way, the orthogonal projection of the opening 30 on the display substrate 100 surrounds a light-emitting region 50. Alternatively, the orthogonal projection of the opening 30 on the display substrate 100 may also be understood as an orthogonal projection, on the display substrate 100, of a region where the opening 30 is located; in this way, the orthogonal projection of the opening 30 on the display substrate 100 covers a light-emitting region 50.

As shown in FIGS. 8A and 8B, in the case where the plurality of sub-pixels P include a plurality of first sub-pixels P1, a plurality of second sub-pixels P2 and a plurality of third sub-pixels P3, the plurality of openings 30 include a plurality of first openings 31, a plurality of second openings 32 and a plurality of third openings 33.

As shown in FIGS. 8A and 8B, an orthogonal projection of each first opening 31 on the display substrate 100 surrounds a first light-emitting region 51 of a first sub-pixel P1; an orthogonal projection of each second opening 32 on the display substrate 100 surrounds a second light-emitting region 52 of a second sub-pixel P2; and an orthogonal projection of each third opening 33 on the display substrate 100 surrounds a third light-emitting region 53 of a third sub-pixel P3. Shapes of the first opening 31, the second opening 32 and the third opening 33 may be the same or different (reference is made to the description below).

As shown in FIGS. 8A, 8B and 9, the color filter layer 320 includes a plurality of filter portions 40, and each filter portion 40 is disposed in an opening 30. The light emitted by the sub-pixel P passes through a filter portion 40 in an opening 30 to become light of a color and then exits.

It can be understood that in order to facilitate the illustration of a corresponding relationship between the opening 30 and the light-emitting region 50 of the sub-pixel P, FIG. 8A does not show the filter portion 40 in the opening 30 of the black matrix layer 310. It can be understood that each opening 30 defines an effective light-emitting region of the display panel 1100. At least part of each filter portion 40 is located in an effective light-emitting region. That is, at least part of each filter portion 40 is located in an opening 30. Therefore, the shape of the filter portion 40 and the shape of the opening 30 may be the same (the filter portion 40 is entirely located in the opening 30); or the shape of the filter portion 40 and the shape of the opening 30 may be different (the filter portion 40 is partially located in the opening 30 and partially located on the black matrix layer 310).

Shapes of the effective light-emitting region and the light-emitting region 50 of the display substrate may be the same or different. That is, the shape of the opening 30 may be the same as the shape of the light-emitting region 50 (as shown in FIG. 8B), or the shape of the opening 30 may be different from the light-emitting region 50 (as shown in FIG. 8A). Each effective light-emitting region is opposite to a single light-emitting region 50, and an orthogonal projection of each effective light-emitting region on the display substrate 100 covers a single light-emitting region 50. That is, the orthogonal projection of each opening 30 on the display substrate 100 covers a single light-emitting region 50.

It can be understood that the light-emitting region 50 refers to a region where each sub-pixel P emits light in the display panel 1100, which is defined by a fourth opening 22′ in the pixel definition layer 22. That is, a shape and size of the light-emitting region 50 are the same as a shape and size of the fourth opening 22′, respectively. The effective light-emitting region refers to a region where the display apparatus 1000 can emit light, which is defined by an opening 30 in the black matrix layer 310. That is, a shape and size of each effective light-emitting region are the same as a shape and size of an opening 30, respectively.

For example, as shown in FIG. 8A, the plurality of sub-pixels P include a plurality of first sub-pixels P1, a plurality of second sub-pixels P2 and a plurality of third sub-pixels P3, and the plurality of openings 30 include a plurality of first openings 31, a plurality of second openings 32 and a plurality of third openings 33. Correspondingly, as shown in FIG. 9, the plurality of filter portions 40 include a plurality of first color filter portions 41, a plurality of second color filter portions 42 and a plurality of third color filter portions 43.

At least part of a first color filter portion 41 is located in a first opening 31, at least part of each second color filter portion 42 is located in a second opening 32, and at least part of each third color filter portion 43 is located in a third opening 33. FIG. 9 illustrates an example in which each first color filter portion 41 is entirely located in a first opening 31, each second color filter portion 42 is entirely located in a second opening 32, and each third color filter portion 43 is entirely located in a third opening 33. It can be understood that a part of the filter portion 40 may be located outside the opening 30. That is, a part of the filter portion 40 and the black matrix layer 310 are stacked. In this way, the reflection of ambient light by the display panel may be further reduced, and the risk of the filter portion 40 falling off from the opening 30 may be reduced. It can be understood that when the filter portion 40 is partially located outside the opening 30, the effective light-emitting region of the sub-pixel P is defined by the opening 30. That is, the light-emitting region and the opening 30 overlap.

In some other embodiments, at least one of the first color filter portion 41, the second color filter portion 42 and the third color filter portion 43 overlaps the black matrix layer 310. For example, the first color filter portion 41 and the second color filter portion 42 are respectively located in the first opening 31 and the second opening 32; a part of the third color filter portion 43 is located in the third opening 33, and another part of the third color filter portion 43 overlaps the black matrix layer 310. In this way, the reflection of ambient light by the color filter structure 300 may be further reduced, thereby reducing the reflection of ambient light by the display apparatus.

The light emitted from the first light-emitting region 51 of the first sub-pixel P1 passes through the first color filter portion 41 located in the first opening 31 to become light of a first color and then exits. The light emitted from the second light-emitting region 52 of the second sub-pixel P2 passes through the second color filter portion 42 located in the second opening 32 to become light of a second color and then exits. The light emitted from the third light-emitting region 53 of the third sub-pixel P3 passes through the third color filter portion 43 located in the third opening 33 to become light of a third color and then exits.

The first color, the second color and the third color may be three primary colors of light (green, blue and red), respectively. In this way, after the light of the first color, the light of the second color and the light of the third color are mixed to create a full range of rich colors. For example, the embodiments of the present disclosure are described by taking an example in which the first color is green, the second color is blue, and the third color is red.

In the related art, in display panels of different display apparatuses, shapes and aperture ratios of light-emitting regions of sub-pixels may be different according to differences in optical requirements of users for different products. For example, the shape of the light-emitting region of the sub-pixel may include a circle, ellipse, quasi-ellipse, rhombus, diamond or other shapes. Correspondingly, the shape of the mesh of the metal mesh structure of the touch layer and the shape of the opening of the black matrix layer each match the shape of the light-emitting region of the sub-pixel. As a result, in different display panels with light-emitting regions of different shapes, touch layers of different structures and black matrix layers of different structures need to be provided. For the manufacturers, the touch layers and color filter structures of different display panels are less universal, causing high production cost. It should be understood that, unless otherwise specified, “different display panels” herein refer to display panels in which the light-emitting regions of the sub-pixels are different in shape or the relative positions of the light-emitting regions are different.

In order to solve the above problem, the embodiments of the present disclosure provide a display panel 1100. Referring to FIG. 7, FIG. 7 is a partial enlarged view of the display panel 1100, and a light-emitting region 50 of a sub-pixel P of the display substrate 100 is located within a reference region 60.

The orthogonal projections of the plurality of metal lines 202 included in the touch layer 200 on the display substrate 100 are located between reference regions 60 where the light-emitting regions 50 of the plurality of sub-pixels P are located. There is a spacing between a metal line 202 adjacent to a light-emitting region 50 of a sub-pixel P and a reference region 60 where the light-emitting region 50 is located. That is, the orthogonal projection of the metal line 202 on the display substrate 100 is located between adjacent reference regions 60, and a spacing exists between the orthogonal projection of the metal line 202 on the display substrate 100 and the reference region 60.

The light-emitting region 50 is located within the reference region 60, and an area of the light-emitting region 50 is less than or equal to an area of the reference region 60. In this way, the metal line 202 is located between adjacent reference regions 60 and has a distance from the reference region 60. Therefore, the metal line 202 may be located between light-emitting regions 50 of adjacent sub-pixels P and has a spacing from the adjacent light-emitting region 50.

For display substrates 100 with different shapes of light-emitting regions 50, as long as light-emitting regions 50 are located within the same reference regions 60 (which are same in shape, same in size, and same in arrangement position), the metal lines 202 may each be located between light-emitting regions 50. In this way, by properly setting the reference region 60 (see below), light-emitting regions 50 of various display substrates 100 with different shapes of light-emitting regions 50 may be located within the same reference region 60. In this way, the metal lines 202 can be applied to the above-mentioned various display panels 1100 with different shapes of light-emitting regions 50. Therefore, the universality of the metal mesh structure 201 is improved, and the universality of the touch layer 200 is improved. As a result, the manufacturing cost of the display apparatus 1000 is reduced.

In some embodiments, as shown in FIG. 8A, among the plurality of openings 30 included in the black matrix layer 310, an orthogonal projection of each opening 30 on the display substrate 100 surrounds a reference region 60, and there is a spacing between a boundary of the opening 30 and a boundary of the reference region 60 surrounded by the opening 30. A shape of the opening 30 is substantially the same as a shape of the reference region 60 surrounded by the opening 30. That is, the shapes of the opening 30 and the reference region 60 surrounded by the opening 30 are similar. For the same reason as improving the universality of the touch layer 200, the universality of the black matrix layer 310 may be improved, and the universality of the color filter structure 300 is improved. The production cost of the color filter structure 300 is reduced, and the production cost of the display apparatus 1000 is reduced.

For example, as shown in FIG. 8A, in the case where the plurality of sub-pixels P include a plurality of first sub-pixels P1, a plurality of second sub-pixels P2 and a plurality of third sub-pixels P3, the plurality of openings 30 include first openings 31, second openings 32 and third openings 33.

An orthogonal projection of each first opening 31 on the display substrate 100 surrounds a first light-emitting region 51 and surrounds a first reference region 61 where the first light-emitting region 51 is located. There is a spacing between a boundary of the first opening 31 and a boundary of the first reference region 61 surrounded by the first opening 31, and the shape of the first opening 31 may be the same as the shape of the first reference region 61 surrounded by the first opening 31.

An orthogonal projection of each second opening 32 on the display substrate 100 surrounds a second light-emitting region 52 and surrounds a second reference region 62 where the second light-emitting region 52 is located. There is a spacing between a boundary of the second opening 32 and a boundary of the second reference region 62 surrounded by the second opening 32, and the shape of the second opening 32 may be the same as the shape of the second reference region 62 surrounded by the second opening 32.

An orthogonal projection of each third opening 33 on the display substrate 100 surrounds a third light-emitting region 53 and surrounds a third reference region 63 where the third light-emitting region 53 is located. There is a spacing between a boundary of the third opening 33 and a boundary of the third reference region 63 surrounded by the third opening 33, and the shape of the third opening 33 may be the same as the shape of the third reference region 63 surrounded by the third opening 33.

In some other embodiments, referring to FIG. 8B, among the plurality of openings 30 included in the black matrix layer 310, the orthogonal projection of each opening 30 on the display substrate 100 surrounds a light-emitting region 50, and the boundary of the opening 30 and the boundary of the light-emitting region 50 surrounded by the opening 30 have a spacing therebetween. The shape of the opening 30 is substantially the same as the shape of the light-emitting region 50 surrounded by the opening 30. That is, the shapes of the opening 30 and the light-emitting region 50 surrounded by the opening 30 are similar. In this way, the optical display effect of the display apparatus 1000 may be improved, the area of the opening 30 of the black matrix layer 310 may be reduced, and the reflection of ambient light by the display panel 1100 may be reduced.

For example, as shown in FIG. 8B, in the case where the plurality of sub-pixels P include a plurality of first sub-pixels P1, a plurality of second sub-pixels P2 and a plurality of third sub-pixels P3, the plurality of openings 30 include first openings 31, second openings 32 and third openings 33.

The orthogonal projection of each first opening 31 on the display substrate 100 surrounds a first light-emitting region 51. There is a spacing between the boundary of the first opening 31 and the boundary of the first light-emitting region 51 surrounded by the first opening 31. The shape of the first opening 31 may be the same as the shape of the first light-emitting region 51 surrounded by the first opening 31.

The orthogonal projection of each second opening 32 on the display substrate 100 surrounds a second light-emitting region 52. There is a spacing between the boundary of the second opening 32 and the boundary of the second light-emitting region 52 surrounded by the second opening 32. The shape of the second opening 32 may be the same as the shape of the second light-emitting region 52 surrounded by the second opening 32.

The orthogonal projection of each third opening 33 on the display substrate 100 surrounds a third light-emitting region 53. There is a spacing between the boundary of the third opening 33 and the boundary of the third light-emitting region 53 surrounded by the third opening 33. The shape of the third opening 33 may be the same as the shape of the third light-emitting region 53 surrounded by the third opening 33.

The shape of the reference region 60 is a closed figure enclosed by at least one straight edge and at least one arc edge.

The reference region 60 may be formed by superimposing the light-emitting regions 50 of at least two display substrates 100 with different light-emitting regions 50 (different in at least one of shape and area). That is, the reference region 60 includes a union of at least two light-emitting regions 50 of different shapes.

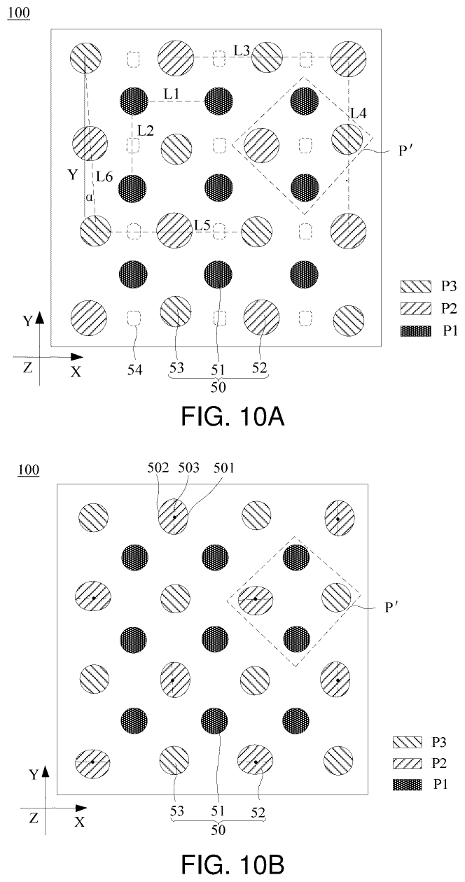

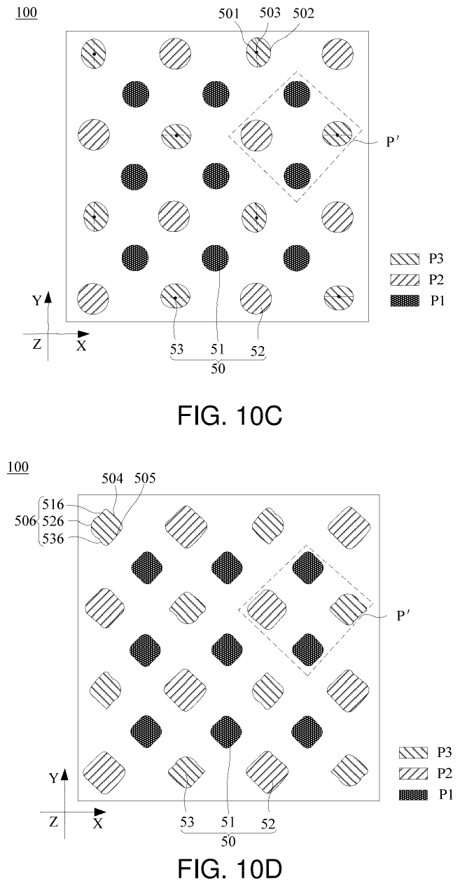

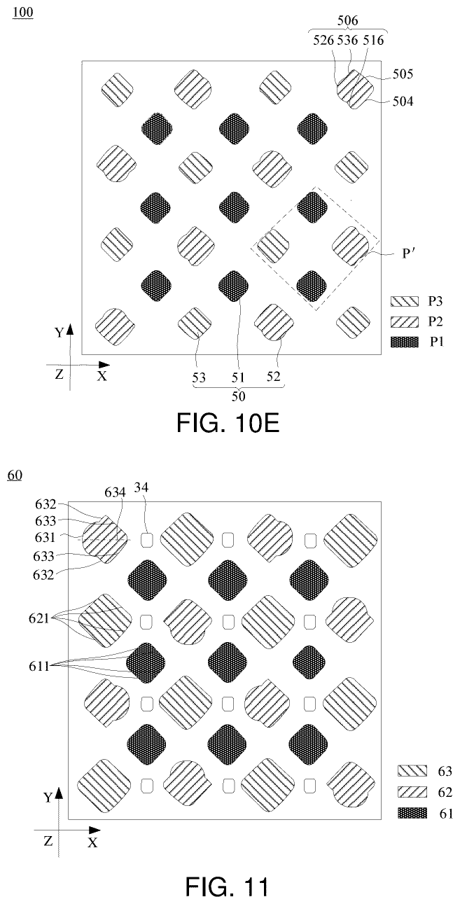

For example, referring to FIG. 10A, the shape of the light-emitting region 50 of the sub-pixel P of the display substrate 100 may be substantially circular. That is, the shape of the first sub-pixel region P1, second sub-pixel region P2 and third sub-pixel region P3 may be substantially circular.

A line L1 connecting centers of two first light-emitting regions 51 of two adjacent first sub-pixels P1 in the first direction X is substantially parallel to the first direction X. A line L2 connecting centers of two first light-emitting regions 51 of two adjacent first sub-pixels P1 in the second direction Y is substantially parallel to the second direction Y. In the embodiments of the present disclosure, the term “substantially parallel” may mean that a deviation range thereof is a deviation within 5°.

A line L3 connecting centers of two second light-emitting regions 52 of two adjacent second sub-pixels P2 in the first direction X is substantially parallel to the first direction X. A line L4 connecting centers of two second light-emitting regions 52 of two adjacent second sub-pixels P2 in the second direction Y is substantially parallel to the second direction Y.

A line L5 connecting centers of two third light-emitting regions 53 of two adjacent third sub-pixels P3 in the first direction X is substantially parallel to the first direction X. A line L6 connecting centers of two third light-emitting regions 53 of two adjacent third sub-pixels P3 in the second direction Y has an included angle a with the second direction Y.

For example, referring to FIGS. 10B and 10C, the shapes of the light-emitting regions 50 of the sub-pixels P in the display substrate 100 may include a circle and a quasi-ellipse. The shape of the first light-emitting region 51 of the first sub-pixel P1 is substantially circular. The shape of one of the second light-emitting region 52 of the second sub-pixel P2 and the third light-emitting region 53 of the third sub-pixel P3 is substantially circular, and the shape of another of the second light-emitting region 52 of the second sub-pixel P2 and the third light-emitting region 53 of the third sub-pixel P3 is substantially a quasi-ellipse.

For example, referring to FIG. 10B, the shapes of the first light-emitting region 51 of the first sub-pixel P1 and the third light-emitting region 53 of the third sub-pixel P3 are substantially circular, and the shape of the second light-emitting region 52 of the second sub-pixel P2 is substantially a quasi-ellipse.

For example, referring to FIG. 10C, the shapes of the first light-emitting region 51 of the first sub-pixel P1 and the second light-emitting region 52 of the second sub-pixel P2 are substantially circular, and the shape of the third light-emitting region 53 of the third sub-pixel P3 is substantially a quasi-ellipse.

In the embodiments of the present disclosure, the quasi-ellipse includes a first curved edge 501 and a second curved edge 502. Two ends of the first curved edge 501 are respectively connected to two ends of the second curved edge 502. A line connecting two connection points of the first curved edge 501 and the second curved edge 502 is a first line segment 503.

The first curved edge 501 and the first line segment 503 enclose a semi-ellipse, and the second curved edge 502 and the first line segment 503 enclose a semicircle. It can be understood that the elliptical-like shape in all embodiments of the present disclosure refers to a figure with the above shape.

For example, referring to FIGS. 10D and 10E, the light-emitting region 50 of the sub-pixel P of the display substrate 100 may be substantially in a shape of a rhombus or substantially in a shape of a diamond. The first light-emitting region 51 of the first sub-pixel P1 may be in a shape of a rhombus. One of the second light-emitting region 52 of the second sub-pixel P2 and the third light-emitting region 53 of the third sub-pixel P3 may be in a shape of a rhombus, and the other is in a shape of a diamond.

For example, referring to FIG. 10D, the first light-emitting region 51 of the first sub-pixel P1 and the second light-emitting region 52 of the second sub-pixel P2 are each in a shape of a rhombus, and the third light-emitting region 53 of the third sub-pixel P3 is in a shape of a diamond.

For example, referring to FIG. 10E, the first light-emitting region 51 of the first sub-pixel P1 and the third light-emitting region 53 of the third sub-pixel P3 are each in a shape of a rhombus, and the second light-emitting region 52 of the second sub-pixel P2 is in a shape of a diamond.

In some embodiments, the light-emitting region 50 is substantially in a shape of a diamond, which means that, as shown in FIG. 10D or FIG. 10E, the boundary of the light-emitting region 50 includes four straight borders and arc angles each connecting two adjacent straight borders. That is, a rhombus may be a rhombus with arc angles.

In the embodiments of the present disclosure, as shown in FIG. 10D or 10E, the “diamond” includes a first straight edge 504, a second straight edge 505, and a third curved edge 506. The first straight edge 504 and the second straight edge 505 are connected to form a first polyline-shaped edge. Two ends of the third curved edge 506 are connected to two ends of the first polyline-shaped edge, respectively. The third curved edge 506 includes a first straight line segment 516, a curved line segment 526 and a second straight line segment 536 connected in sequence. The first straight line segment 516 is connected to the first straight edge 504, and the second straight line segment 536 is connected to the second straight edge 505. It can be understood that the “diamond” in all embodiments of the present disclosure refers to a figure with the above shape.

It can be understood that, as shown in FIG. 10D or 10E, the first straight edge 504 and the second straight edge 505 are connected through an arc angle, the first straight line segment 516 and the first straight edge 504 are connected through an arc angle, and the second straight line segment 536 and the second straight edge 505 are connected through an arc angle. That is, two connected straight edges are connected through an arc angle.

In the embodiments of the present disclosure, the reference regions 60 may be formed by superimposing at least two of various display substrates 100 with different shapes of light-emitting regions 50 as shown in FIGS. 10A to 10D. In this way, light-emitting regions 50 of sub-pixels P of the at least two display substrates 100 may be located within the reference region 60. Furthermore, orthogonal projections of the plurality of metal lines 202 of the touch layer 200 on the display substrate 100 may be located between the light-emitting regions 50 of the plurality of sub-pixels P of any of the at least two display substrates 100 mentioned above. Based on this, the plurality of metal lines 202 of the metal mesh structure 201 may be applied to the above-mentioned at least two display substrates 100 with different shapes of light-emitting regions, thereby improving the universality of the metal mesh structure 201 and in turn improving the universatility of the touch layer 200. That is, the touch layer 200 provided in the embodiments of the present disclosure may be applied to at least two display substrates 100 with different shapes of light-emitting regions 50, thereby reducing the manufacturing cost of the display panel 1100.

In some embodiments, the orthogonal projection of each opening of the black matrix layer 310 on the display substrate 100 surrounds a reference region 60, and the shape of the opening 30 of the black matrix layer 310 is substantially the same as the shape of the reference region 60 surrounded by the orthogonal projection of the opening 30 on the display substrate 100. In this way, based on the same reason of the touch layer 200, the black matrix layer 310 may be adapted to (compatible with) various display substrates 100 with different shapes of light-emitting regions 50, thereby improving the universatility of the color filter structure 300 and reducing the manufacturing cost of the color filter structure 300.

In some other embodiments, the orthogonal projection of each opening of the black matrix layer 310 on the display substrate 100 surrounds a light-emitting region 50, and the shape of the opening 30 of the black matrix layer 310 is substantially the same as the shape of the light-emitting regions 50 surrounded by the orthogonal projection of the opening 30 on the display substrate 100. In this way, it may be possible to reduce the color separation phenomenon of the display apparatus and reduce the reflection of ambient light by the display apparatus 1000, and in turn improve the optical display effect of the display apparatus 1000.

For example, referring to FIG. 11, FIG. 11 shows a reference region 60 formed by superimposing various display substrates 100 with different shapes of light-emitting regions 50. The reference regions 60 shown in FIG. 11 is formed by superimposing five display substrates 100 with different shapes of light-emitting regions 50 shown in FIGS. 10A to 10E. In this way, the light-emitting regions 50 of the sub-pixels P of at least the above-mentioned five display substrates 100 may be located within the reference region 60 shown in FIG. 11. Therefore, in the case where the orthogonal projections of the metal lines 202 of the metal mesh structure 201 on the display substrate 100 are located between reference regions 60 where the light-emitting regions are located, and each have a spacing from an adjacent reference region 60; and the metal mesh structure 201 may be applied to the above five display substrates 100. Based on this, the universality of the touch layer 200 may be greatly improved, and the manufacturing cost of the display panel 1100 is reduced.

In the case where the orthogonal projection of the opening 30 of the black matrix layer 310 on the display substrate 100 surrounds a reference region 60 and has a spacing from the boundary of the surrounded reference region 60, based on the same reason as above, the universality of the black matrix layer 310 can be improved, and the universality of the color filter structure 300 is improved. As a result, the manufacturing cost of the display panel 1100 is reduced.

Referring to FIG. 11, a plurality of reference regions 60 may include a plurality of first reference regions 61, a plurality of second reference regions 62 and a plurality of third reference regions 63. A first light-emitting region 51 of each first sub-pixel P1 is located within a first reference region 61, a second light-emitting region 52 of each second sub-pixel P2 is located within a second reference region 62, and a third light-emitting region 53 of each third sub-pixel P3 is located within a third reference region 63.

The first reference region 61 is substantially in a shape of a rhombus, and includes four first virtual straight edges 611 connected end to end. The first virtual straight edges 611 are substantially straight lines. For example, two adjacent first virtual straight edges 611 are connected through an arc angle.

Similar to the shape of the first reference region 61, the second reference region 62 is substantially in a shape of a rhombus. The second reference region 62 includes four second virtual straight edges 621 connected end to end. The second virtual straight edges 621 are substantially straight lines. For example, two adjacent second virtual straight edges 621 are connected through an arc angle.

A boundary of the third reference region 63 includes one virtual arc edge 631, two third virtual straight edges 632, and two fourth virtual straight edges 633. The third virtual straight edges 632 and the fourth virtual straight edges 633 are substantially straight lines. Two ends of the virtual arc edge 631 are each connected to an end of a single third virtual straight edge 632. Another end of the third virtual straight edge 632 is connected to a single fourth virtual straight edge 633. Another ends of the two fourth virtual straight edges 633 are connected to each other. The third reference region 63 has a second symmetry axis 634, the second symmetry axis 634 passing through a midpoint of the virtual arc edge 631 and a connection point of the two fourth virtual straight edges.

It can be understood that the light-emitting region 50 is defined by a region where the sub-pixel P can emit light, which may have the same shape as the fourth opening 22′ in the pixel definition layer 22. That is, the light-emitting region 50 actually exists in the display substrate 100, is defined by the fourth opening 22′ in the pixel definition layer 22, and is the region where the sub-pixel P can emit light. Different from the light-emitting region 50, the reference region 60 is a virtual region defined by humans, which is a region introduced as a reference for designing the touch layer 200 and the color filter structure 300, rather than an actual structure existing in the display substrate 100. Therefore, the boundary of the reference region 60 can be understood as a virtual boundary.

It can be understood that when designing the touch layer 200 and the color filter structure 300 of the display panel 1100 for universality, various display substrates 100 with different shapes of light-emitting regions of sub-pixels P where the sub-pixels P are substantially arranged in the same manner are usually selected for superimposing to form reference regions 60. That is to say, the shapes of the light-emitting regions of the sub-pixels P of the display substrates 100 are different, but the sub-pixels P of the display substrates 100 are substantially arranged in the same manner and the aperture ratios of different sub-pixels P are substantially the same.

For example, as shown in FIGS. 10A to 10E, the plurality of sub-pixels P of the display substrates 100 are substantially arranged in the same manner; the aperture ratios of the first sub-pixels P1 of different display substrates 100 are approximately the same; the aperture ratios of the second sub-pixels P2 of different display substrates 100 are substantially the same; and the aperture ratios of the third sub-pixel P3 of different display substrates 100 are substantially the same.

For example, the plurality of sub-pixels P may include a plurality of pixel groups P′, and each pixel group P′ includes two first sub-pixels P1, one second sub-pixel P2 and one third sub-pixel P3. In a pixel group P′, two first sub-pixels P1 are arranged in the second direction Y, and the second sub-pixel P2 and the third sub-pixel P3 are arranged in the first direction X. A center connection line of the two first sub-pixels P1 intersects a center connection line of the second sub-pixel P2 and the third sub-pixel P3. When the display substrate 100 is used for display, in a pixel group P′, the two first sub-pixels P1 may be combined with the second sub-pixel P2 and the third sub-pixel P3 respectively, so as to form two independent light-emitting pixel points. Thereby, a high resolution is realized through pixel borrowing principle. It should be noted that the term “center connection line” refers to a line connecting centers of light-emitting regions 50 of two sub-pixels P; and the term “center” may be a geometric center of a light-emitting region 50.

It can be understood that based on the above-mentioned reference region 60, the display substrate 100 with other shapes of light-emitting regions 50, as long as light-emitting regions 50 of sub-pixels P are each located within a single reference region 60, the touch layer 200 can also be applicable to the display substrate 100.

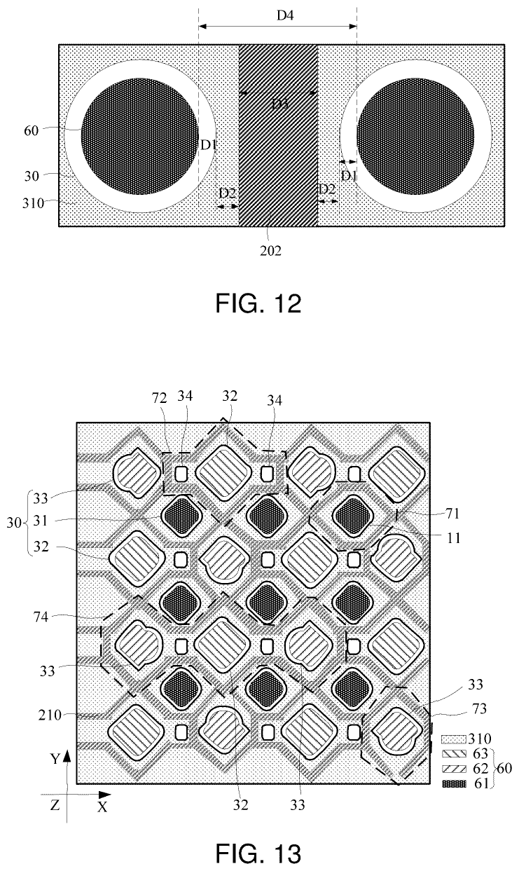

Referring to FIG. 12, FIG. 12 is a diagram showing a structure of the position design of the metal line 202. In some embodiments, the spacing between the orthogonal projection of the boundary of the opening 30 of the black matrix layer 310 on the display substrate 100 and the boundary of the reference region 60 surrounded by the opening 30 is D1. The light-emitting region 50 of the sub-pixel P is located within the reference region 60, and the area of the light-emitting region 50 is less than or equal to the area of the reference region 60. Therefore, the spacing between the orthogonal projection of the boundary of the opening 30 on the display substrate 100 and the light-emitting region 50 of the sub-pixel P surrounded by the opening 30 is greater than or equal to D1.

In some embodiments, the spacing D1 between the orthogonal projection of the boundary of the opening 30 on the display substrate 100 and the boundary of the reference region 60 surrounded by the opening 30 is greater than or equal to 2.5 μm. In this way, at least part of divergent light emitted from the light-emitting region 50 passes through the filter portion 40 (not shown in the figure) in the opening 30 and exits from the display panel 1100, thereby improving the light extraction efficiency of the display panel 1100. Moreover, it is conducive to improving the field of view of the display apparatus 1000.

For example, the spacing may be 2.5 μm, 2.8 μm, or 3.0 μm, which will not be described in detail in the embodiments of the present disclosure. It can be understood that the spacing D1 is not necessarily the larger the better. The larger the spacing D1, the larger the opening 30 of the black matrix layer 310, and the stronger the reflection of ambient light by the display panel 1100, which is not conducive to the use of the display panel 1100 in a lighting environment. For example, the spacing D1 may be less than or equal to 4 μm. Of course, the above spacing D1 may also be adjusted according to actual requirements for the optical performance of the display panel 1100.

It can be understood that, in consideration of the critical dimension bias (CD bias) in the process of forming the openings 30 in the black matrix layer 310, in the current process, a single border of the opening 30 shrinks inwardly by X μm (i.e., an offset in a direction away from the reference region 60). That is, the actual size of a single border of the opening 30 may be greater than the design value by X μm. In this way, the design value of the spacing D1 may be greater than or equal to (4−X) μm. For example, in the current manufacturing process, a single edge of the opening 30 shrinks inwardly by about 0.6 μm; therefore, the design value of the spacing D1 is greater than or equal to 3.4 μm.

A spacing between the orthogonal projection of the boundary of the opening 30 on the display substrate 100 and a boundary of the orthogonal projection of the metal line 202 on the display substrate 100 is D2. That is, the orthogonal projection of the black matrix layer 310 on the display substrate 100 covers the orthogonal projection of the metal line 202 on the display substrate 100. The black matrix layer 310 can block the metal line 202, thereby reducing the reflection of ambient light by the metal line 202 and improving the contrast ratio of the display panel 1100.

In some embodiments, the spacing D2 between the orthogonal projection of the boundary of the opening 30 on the display substrate 100 and the orthogonal projection of the metal line 202 on the display substrate 100 is greater than or equal to 4 μm. In this way, the black matrix layer 310 can completely block the metal line 202, thus reducing the reflection of ambient light by the metal line 202 to a great extent. For example, the spacing D2 may be 4 μm, 4.3 μm, 4.5 μm, or 5 μm, which will not be described in detail in the embodiments of the present disclosure.

In some embodiments, a line width of the metal line 202 is D3, and D3 is greater than or equal to 3 μm, which is conducive to reducing the resistance of the metal line 202 and in turn reducing the resistance of the metal mesh structure 201. For example, the line width D3 of the metal line 202 may be 3 μm, 4 μm, 4.3 μm, 4.5 μm, or 5 μm, which will not be described in detail in the embodiments of the present disclosure. It can be understood that within the scope of space allowance, the wider the line width of the metal line 202, the better.

D3=D4−2×D1−2×D2. That is, D4=D3+2×D1+2×D2. Here, a spacing between boundaries of light-emitting regions 50 of two adjacent sub-pixels P is D4.

In the case where the spacing D1 is greater than or equal to 2.5 μm, D2 is greater than or equal to 4 μm, and D3 is greater than or equal to 4 μm, the spacing D4 between the boundaries of the light-emitting regions 50 of two adjacent sub-pixels P is greater than or equal to 17 μm. In this way, the arrangement of the metal lines 202 is facilitated. For example, the spacing D4 between the boundaries of the light-emitting regions 50 of two adjacent sub-pixels P may be 19 μm, 21 μm, 22 μm, or 23 μm, which will not be described in detail in the embodiments of the present disclosure.

In the actual manufacturing process, the aperture ratio and arrangement of the light-emitting region 50 of each sub-pixel P may be designed according to various optical properties of the display panel 1100; after the aperture ratio and arrangement of the light-emitting region 50 of the sub-pixel P are set, the spacing D4 between the boundaries of the light-emitting regions 50 of two adjacent sub-pixels P is determined.

Then, based on the shape, position, arrangement and size of the reference region 60 as well as the spacing D2 being greater than or equal to 3 μm, the black matrix layer 310 is designed, and the position, shape and size of the opening 30 of the black matrix layer 310 are determined. Next, according to D3=D4−2×D1−2×D2, the space that can be used to set the metal line 202 is determined. Then, the metal line 202 only needs to be set within the space that can be used to set the metal line 202 (within the spacing determined by D3).

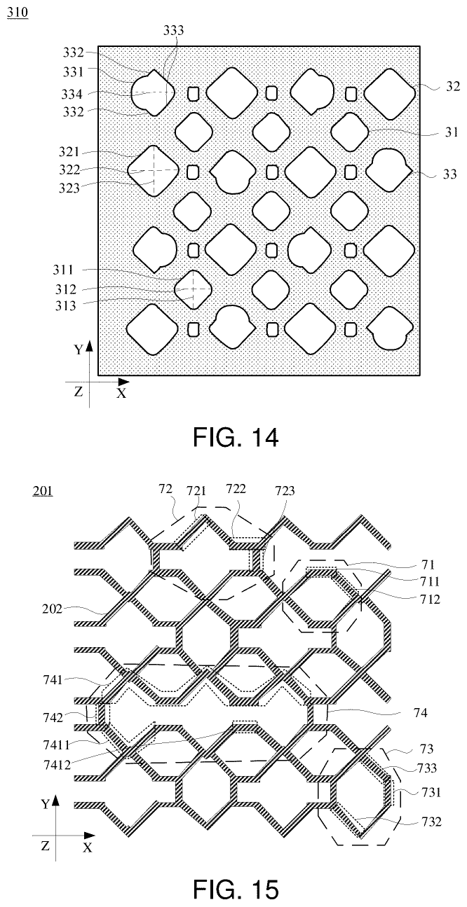

For example, referring to FIGS. 13 and 14, FIG. 13 shows a structure of a black matrix layer 310 arranged according to the reference regions 60 in FIG. 11 and a structure of a metal mesh structure 201 arranged according to the reference regions 60 in FIG. 11 in a case where the orthogonal projection of each opening 30 on the display substrate 100 surrounds a reference region 60. FIG. 14 is a structural diagram of the black matrix layer 310 in FIG. 13. The plurality of openings 30 of the black matrix layer 310 include a plurality of first openings 31, a plurality of second openings 32 and a plurality of third openings 33.

Similar to the shape of the first reference region 61, the first opening 31 is substantially in a shape of a rhombus. The first opening 31 includes four first borders 311 connected end to end, and the first borders 311 are substantially straight lines. A diagonal line 312 of the first opening 31 extends substantially in the first direction X, and another diagonal line 313 of the first opening 31 extends substantially in the second direction Y. It can be understood that, referring to FIG. 14, two adjacent first borders 311 are connected through a short arc border. The orthogonal projection of the first opening 31 on the display substrate 100 surrounds a first reference region 61.

As shown in FIGS. 13 and 14, similar to the shape of the second reference region 62, the second opening 32 is substantially in a shape of a rhombus. The second opening 32 includes four second borders 321 connected end to end. The second borders 321 are substantially straight lines. A diagonal line 322 of the second opening 32 extends substantially in the first direction X, and another diagonal line 323 substantially extends in the second direction Y. The orthogonal projection of the second opening 32 on the display substrate 100 surrounds a second reference region 62.

The shape of the second opening 32 is the same as the shape of the first opening 31. In the case where the plurality of sub-pixels P include a plurality of first sub-pixels P1 and a plurality of second sub-pixels P2, the area of the second light-emitting region 52 of the second sub-pixel P2 is greater than the area of the first light-emitting region 51 of the first sub-pixel P1. Based on this, the area of the second opening 32 is greater than the area of the first opening 31 (or the aperture ratio of the second opening 32 is greater than the aperture ratio of the first opening 31).

As shown in FIGS. 13 and 14, the third opening 33 includes one arc border 331, two third borders 332 and two fourth borders 333. The two third borders 332 and the two fourth borders 333 are substantially straight lines. Two ends of the arc border 331 are each connected to an end of a single third border 332. Another end of the third border 332 is connected to a single fourth border 333. Another ends of the two fourth borders 333 are connected to each other. The third opening 33 has a first symmetry axis 334 passing through a midpoint of the arc border 331 and a connection point of the two fourth borders 333. The orthogonal projection of the third opening 33 on the display substrate 100 surrounds a third reference region 63.

The arc border 331 and the two third borders 332 form a curved-shaped border, and the two fourth borders 333 form a polyline-shaped border. The curved-shaped border and the polyline-shaped border are arranged in an order. The curved-shaped borders and the polyline-shaped borders of two adjacent third openings 33 in the first direction X are arranged in opposite orders. First symmetry axes 334 of third openings 33 in two adjacent rows are substantially perpendicular to each other.

Referring to FIGS. 13, 14 and 15, FIG. 15 is a structural diagram of the metal mesh structure 201 in FIG. 13. The metal mesh structure 201 includes a plurality of first meshes 71, a plurality of second meshes 72, a plurality of third meshes 73 and a plurality of fourth meshes 74.

The first mesh 71 is substantially hexagonal, and includes two first extension sections 711 that are oppositely arranged and extend in the first direction X and four second extension sections 712 that are respectively substantially parallel to the four first borders 311. An orthogonal projection of each first mesh 71 on the display substrate 100 surrounds an orthogonal projection of a first opening 31 on the display substrate 100.

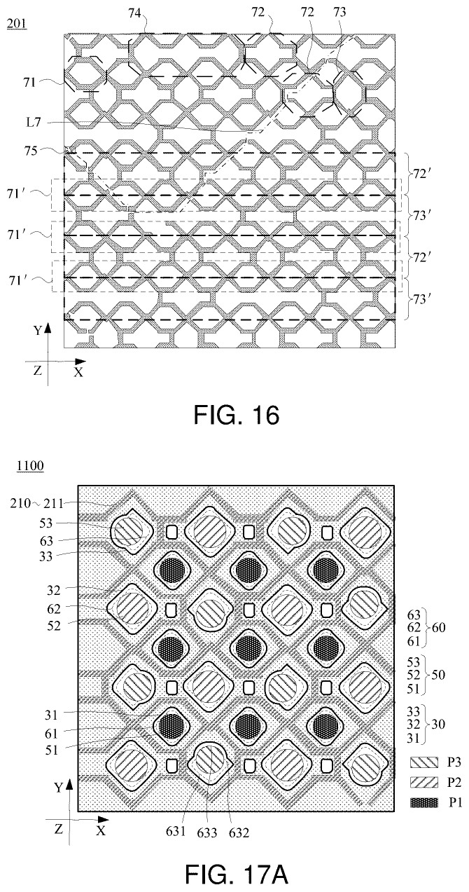

Referring to FIG. 16, FIG. 16 is a structural diagram of the metal mesh structure 201 (including more meshes) in a large region in order to illustrate the arrangement manner of more parts of the metal mesh structure 201. In a case where the plurality of first sub-pixels are arranged in multiple rows and multiple columns, in the first direction X, a plurality of first meshes 71 are connected to form a first mesh row 71′, and there is a spacing between two adjacent first mesh rows 71′ in the second direction Y.

Referring to FIGS. 13, 14 and 15, an orthogonal projection of a second mesh 72 on the display substrate 100 surrounds an orthogonal projection of a second opening 32 on the display substrate 100. The second mesh 72 includes four third extension sections 721. In a case where the second opening 32 is substantially in a shape of a rhombus, the four third extension sections 721 are substantially parallel to the four second borders 321 of the second opening 32, respectively. In this way, the spacing between the third extension section 721 and the second border 321 may be approximately equal, which is conducive to improving the uniformity of the wiring of the metal lines 202.

In some embodiments, the black matrix layer 310 further includes a plurality of light-transmitting holes 34. Two sides of the second opening 32 in the first direction X are each provided with a light-transmitting hole 34, and a light-transmitting hole 34 is located between two adjacent first openings 31 in the second direction Y. The light-transmitting holes 34 are used to improve the light transmittance of the display panel 1100, which facilitates light-capturing of a functional device (such as a distance sensor, a fingerprint recognition module, a front-facing camera, etc.) on a side away from the light-exit side of the display substrate 100.

As shown in FIG. 10A, the display substrate 100 may further include light-transmitting regions 54 corresponding to the plurality of light-transmitting holes 34. The light-transmitting regions 54 are used to improve the light transmittance of the display substrate 100. For example, the conductive layers included in the display substrate 100 are all located outside the light-transmitting regions 54, which is conducive to improving the light transmittance of the light-transmitting regions 54.

For example, the display panel 1100 includes a high light-transmitting region. The high light-transmitting region may be a part of the display region AA, or the entire display region AA may be the high light-transmitting region. In the case where the high light-transmitting region is a part of the display region AA, a part of a portion of the black matrix layer 310 located in the display region AA is provided therein with the light-transmitting holes 34, so that the light transmittance of the high light-transmitting region is greater than that of other regions. In the case where the entire display region AA is the high light-transmitting region, the entire portion of the black matrix layer 310 located in the display region AA is provided therein with the light-transmitting holes 34, so that the light transmittance of the high light-transmitting region (display region AA) is approximately identical.

For example, the entire portion of the black matrix layer 310 located in the display region AA is provided therein with the light-transmitting holes 34. In this way, different display apparatuses 1000 may all have high light-capturing effects no matter where functional devices are placed. As a result, the universatility of the display panel 1100 is improved.

As shown in FIG. 13, the orthogonal projection of the second mesh 72 on the display substrate 100 also surrounds the orthogonal projections, on the display substrate 100, of the two light-transmitting holes 34 on the two sides of the second opening 32 in the first direction X. That is, the second mesh 72 also surrounds the two light-transmitting holes 34. It can be understood that a spacing between a boundary of the orthogonal projection of the second mesh 72 on the display substrate 100 and a boundary of the orthogonal projection of the light-transmitting hole 34 on the display substrate 100 may be approximately the same as the above-mentioned spacing D2 (the spacing between the orthogonal projection of the boundary of the opening 30 on the display substrate 100 and the orthogonal projection of the metal line 202 on the display substrate 100).

As shown in FIG. 15, the second mesh 72 further includes four fourth extension sections 722 extending in the first direction X and two fifth extension sections 723 extending in the second direction Y. Each two fourth extension sections 722 constitute a group, and the two fourth extension sections 722 are respectively located on two sides of a single light-transmitting hole 34 in the second direction Y; an end of the fourth extension section 722 close to the second opening 32 is connected to a single third extension section 721; and a fifth extension section 723 is connected to two ends of a group of two fourth extension sections 722 away from the second opening 32. That is, a group of fourth extension sections 722 and a fifth extension section 723 form a rectangle with a gap, and the gap faces the second opening and extends along a periphery of a light-transmitting hole.

For example, when the metal mesh structure 201 includes a plurality of first meshes 71 and a plurality of second meshes 72, an extension section of the first mesh 71 and an extension section of the second mesh 72 that are close to each other share a metal line. For example, the first extension section 711 of the first mesh 71 and the fourth extension section 722 of the second mesh 72 share a metal line 202, and the second extension section 712 and the third extension section 721 of the second mesh 72 share a metal line 202. In this way, it is conducive to simplifying the pattern of the metal mesh structure 201 and reducing the difficulty of forming the metal mesh structure 201.

As shown in FIGS. 13, 14 and 15, the third mesh 73 is substantially hexagonal, and includes: two sixth extension sections 731 extending in the second direction Y, two seventh extension sections 732 that are respectively substantially parallel to the third borders 332 (of the third opening 33), and two eighth extension sections 733 that are respectively substantially parallel to the fourth borders 333 (of the third opening 33). An orthogonal projection of each third mesh 73 on the display substrate 100 surrounds a third reference region 63 whose first symmetry axis 334 extending in the second direction Y.

Referring to FIGS. 10A to 10E, a third sub-pixel P3 is located between four adjacent first sub-pixels P1 that are arranged in two rows and two columns. In this way, a third mesh 73 is located between four first meshes 71 respectively surrounding the four first sub-pixels P1. Since the plurality of second sub-pixels P2 and the plurality of third sub-pixels P3 are alternately arranged in the first direction X, two second sub-pixels P2 are respectively arranged on two sides of the third sub-pixel P3 in the first direction X. That is to say, two second meshes 72 are respectively arranged on two sides of the third mesh 73 in the first direction X. In this way, an extension section of the third mesh 73 and an extension section of the first mesh 71 that are adjacent share a metal line 202, and an extension section of the third mesh 73 and an extension section of the second mesh 72 that are adjacent share a metal line 202.

For example, as shown in FIG. 15, the sixth extension section 731 of the third mesh 73 and a fifth extension section 723 of a second mesh 72 share a metal line 202, the seventh extension section 732 and an adjacent second extension section 712 of a first mesh 71 share a metal line 202, and the eighth extension section 733 and an adjacent second extension section 712 of a first mesh 71 share a metal line 202.

As shown in FIG. 14, the plurality of third sub-pixels P3 are arranged in multiple rows and multiple columns. First symmetry axes 334 of third openings 33 in the black matrix layer 310 corresponding to third sub-pixels P3 in the same row are parallel to each other. First symmetry axes 334 of third openings 33 in two adjacent rows are substantially perpendicular to each other.

In a case where first symmetry axis 334 of a plurality of third openings 33 in a row extend substantially in the second direction Y and two adjacent third openings 33 are arranged in rotational symmetry, as shown in FIG. 16, the plurality of third meshes 73 and the plurality of second meshes 72 are alternately arranged in the first direction X.

As shown in FIG. 15, the fourth mesh 74 includes two polyline-shaped extension sections 741 that are oppositely arranged and two ninth extension sections 742 extending in the second direction Y. The polyline-shaped extension section 741 includes three V-shaped sub-sections 7411 that are spaced apart in the first direction X and two straight sub-sections 7412 that are each connected to two adjacent V-shaped sub-sections 7411. V-shaped sub-sections 7411 of the two polyline-shaped extension sections 741 protrude in directions away from each other. The ninth extension section 742 extends in the second direction Y and connects ends of the two polyline-shaped extension sections. The fourth mesh 74 is substantially of a strip-shaped structure with polyline-shaped borders.

As shown in FIG. 13, an orthogonal projection of each fourth mesh 74 on the display substrate 100 surrounds orthogonal projections, on the display substrate 100, of two adjacent third openings 33 in the first direction X and one second opening 32 located between the two third openings 33. First symmetry axes 334 of the two adjacent third openings 33 are substantially parallel to the first direction X, and two arc borders 331 of the two third openings 33 are close to the second opening 32.

In a case where the symmetry axis 334 of the third opening 33 extends substantially in the first direction X, the size of the third opening 33 in the first direction is large. The spacing between the first border 311 of the third opening 33 and the adjacent second opening 31 is less than the minimum wiring space requirement of the metal line 202, and it is insufficient to arrange the metal line 202. The spacing between the fourth border 333 of the third opening 33 and the second opening 32 meets the minimum wiring space requirement of the metal line 202. Therefore, the metal line 202 extending in the second direction Y may be arranged between the fourth border 333 of the third opening 33 and the second opening 32. Based on this, the fourth mesh 74 of the above shape may be formed.

In some embodiments, as shown in FIG. 15, the metal mesh structure 201 includes a plurality of first meshes 71 and a plurality of second meshes 72, an extension section of the fourth mesh 74 and an extension section of the first mesh 71 that are adjacent share a metal line 202, and an extension section of the fourth mesh 74 and an extension section of the second mesh 72 that are adjacent share a metal line 202.

For example, in the polyline-shaped extension section 741 of the fourth mesh 74, a V-shaped sub-section 7411 shares a metal line 202 with a second extension section 712 of the first mesh 71, and a straight sub-section 7412 shares a metal line 202 with a first extension section 711 of the first mesh 71. A ninth extension section of the fourth mesh 74 and a fifth extension section 723 of the second mesh 72 share a metal line 202.

For example, referring to FIG. 16, when the first symmetry axes 334 of a plurality of third openings 33 in a row extend substantially in the first direction X, a plurality of fourth meshes 74 and a plurality of second meshes 72 are alternately arranged in first directions X, and two adjacent third openings 33 are arranged symmetrically.

A plurality of third meshes 73 and a plurality of second meshes 72 alternately arranged in the first direction X constitute a second mesh row 72′. A plurality of fourth meshes 74 and a plurality of second meshes 72 alternately arranged in the first direction X constitute a third mesh row 73′. In the second direction Y, second mesh rows 72′ and third mesh rows 73′ are alternately arranged, and a first mesh row 71′ is provided between a second mesh row 72′ and a third mesh row 73′ that are adjacent.

As shown in FIG. 16, the metal mesh structure 201 further includes a plurality of fifth openings 75, and the plurality of fifth openings 75 separate the metal mesh structure 201 to form a plurality of first touch electrodes 212 and a plurality of second touch electrodes 213. For example, by connecting a plurality of fifth openings 75 with a dotted line L7, the metal mesh structure 201 shown in FIG. 16 can be divided into one upper touch electrode and one lower touch electrode (a first touch electrode and a second touch electrode).

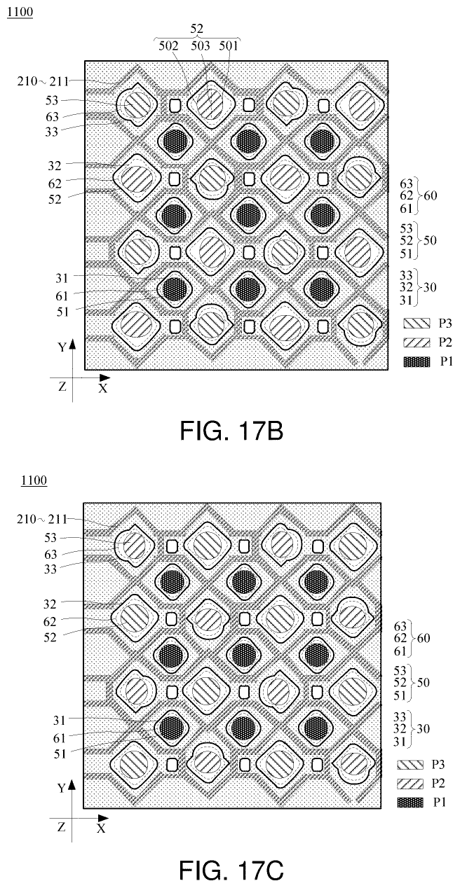

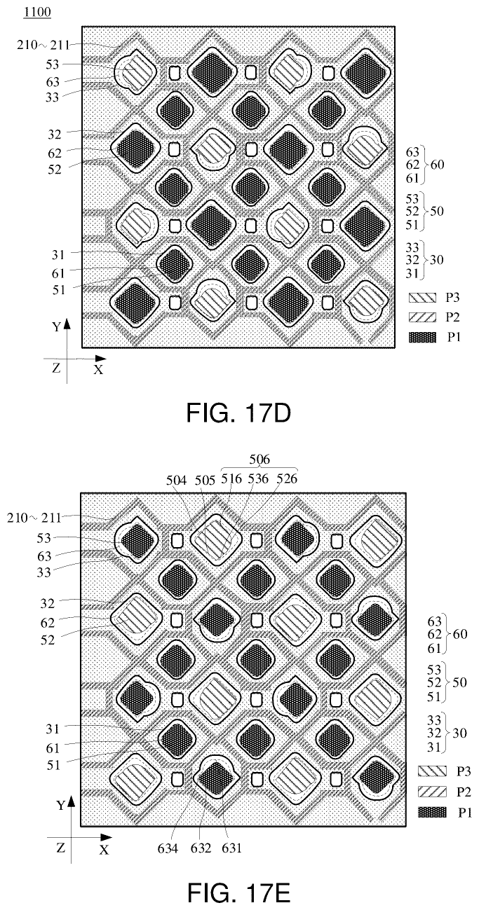

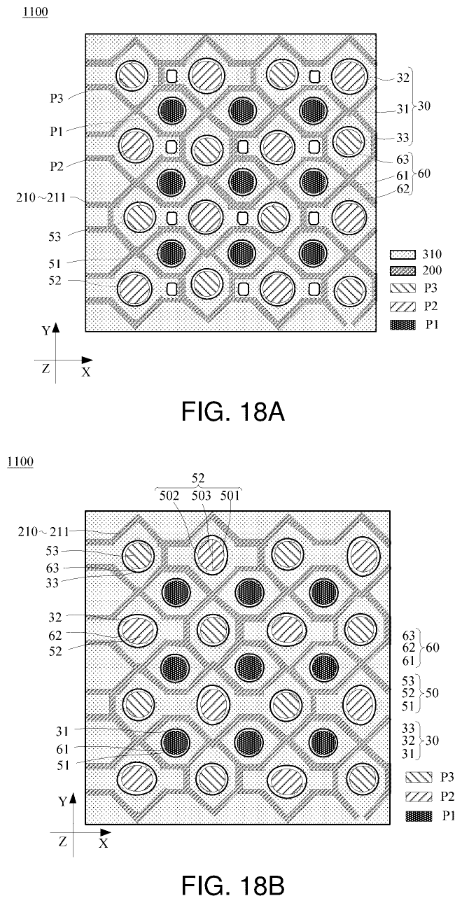

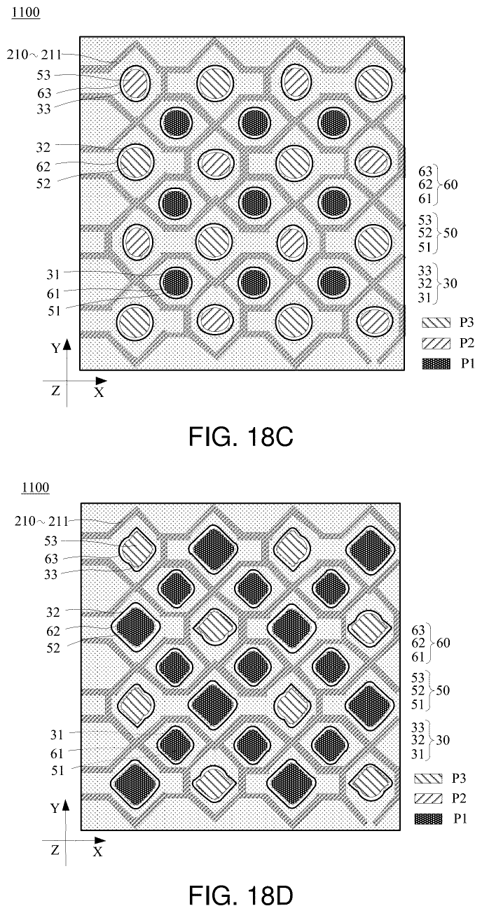

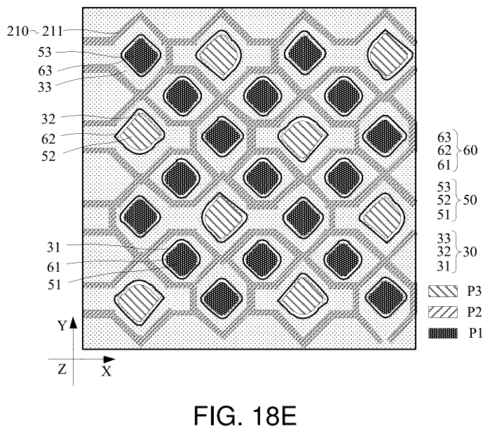

In some embodiments, the touch layer 200 can be disposed on any one of the display substrates 100 as shown in FIGS. 10A to 10E, so as to form a display panel 1100 as shown in FIGS. 17A to 17E or FIGS. 18A to 18E. It can be understood that in the case where the orthogonal projection of the opening 30 of the black matrix layer 310 on the display substrate 100 surrounds a reference region 60 and has the same shape as the reference region, the display panels as shown in FIGS. 17A to 17E are formed; in the case where the orthogonal projection of the opening 30 of the black matrix layer 310 on the display substrate 100 surrounds a light-emitting region 50 and has the same shape as the light-emitting region 50, the display panels as shown in FIGS. 18A to 18E are formed.

For example, as shown in FIG. 17A, the light-emitting region 50 of the sub-pixel P is substantially in a shape of a circle. The first light-emitting region 51 of the first sub-pixel P1 is substantially in a shape of a circle, and the boundary of the first light-emitting region 51 is tangent to the first reference region 61. The second light-emitting region 52 of the second sub-pixel P2 is substantially in a shape of a circle, and the boundary of the second light-emitting region 52 is tangent to the second reference region 62. The third light-emitting region 53 of the third sub-pixel P3 is substantially in a shape of a circle, part of the boundary of the third light-emitting region 53 substantially overlaps with the virtual arc edge of the third reference region 63, and part of the boundary of the third light-emitting region 53 is located within the third reference region 63 and has a distance from the boundary of the third reference region 63.

It can be understood that when the area of the first light-emitting region 51 is small, the boundary of the first light-emitting region 51 may also have a distance from at least one first virtual straight edge of the first reference region 61; when the area of the second light-emitting region 52 is small, the boundary of the second light-emitting region 52 may also have a distance from at least one second virtual straight edge of the second reference region 62.

The orthogonal projection of the opening 30 of the black matrix layer 310 on the display substrate 100 surrounds a reference region 60 and has the same shape as the surrounded reference region 60. For example, the orthogonal projection of each first opening 31 on the display substrate 100 surrounds a first reference region 61, and the shape of the first opening 31 is the same as the shape of the first reference region 61 surrounded by the first opening 31; the orthogonal projection of each second opening 32 on the display substrate 100 surrounds a second reference region 62, and the shape of the second opening 32 is the same as the shape of the second reference region 62 surrounded by the second opening 32; the orthogonal projection of each third opening 33 on the display substrate 100 surrounds a third reference region 63, and the shape of the third opening 33 is the same as the shape of the third reference region 63 surrounded by the third opening 33.

For example, referring to FIG. 18A, in the display panel shown in FIG. 18A and the display panel shown in FIG. 17A, the display substrates 100 may have the same structure and the touch layers 200 may have the same structure, which will not be repeated here. As shown in FIG. 18A, the orthogonal projection of the opening 30 of the black matrix layer 310 on the display substrate 100 surrounds a light-emitting region 50 and has the same shape as the surrounded light-emitting region 50. For example, the orthogonal projection of each first opening 31 on the display substrate 100 surrounds a first light-emitting region 51, and the shape of the first opening 31 is the same as the shape of the first light-emitting region 51 surrounded by the first opening 31; the orthogonal projection of each second opening 32 on the display substrate 100 surrounds a second light-emitting region 52, and the shape of the second opening 32 is the same as the shape of the second light-emitting region 52 surrounded by the second opening 32; the orthogonal projection of each third opening 33 on the display substrate 100 surrounds a third light-emitting region 53, and the shape of the third opening 33 is the same as the shape of the third light-emitting region 53 surrounded by the third opening 33.

For example, as shown in FIG. 17B, the shape of the first light-emitting region 51 of the first sub-pixel P1 and the shape of the third light-emitting region 53 of the third sub-pixel P3 are each substantially a circular shape, and the shape of the second light-emitting region 52 of the second sub-pixel P2 is substantially a quasi-ellipse.

The boundary of the first light-emitting region 51 is tangent to the first reference region 61. A border of the second light-emitting region 52 that is formed by the first curved edge 501 has a distance from the second reference region 62. A border of the second light-emitting region 52 that is formed by the second curved edge 502 is tangent to the boundary of the second reference region 62. The boundary of the third light-emitting region 53 is tangent to the fourth virtual straight edges 633 of the third reference region 63.

The orthogonal projection of the opening 30 of the black matrix layer 310 on the display substrate 100 surrounds a reference region 60 and has the same shape as the surrounded reference region 60.

For example, referring to FIG. 18B, in the display panel shown in FIG. 18B and the display panel shown in FIG. 17B, the display substrates 100 may have the same structure and the touch layers 200 may have the same structure, which will not be repeated here. As shown in FIG. 18B, the orthogonal projection of the opening 30 of the black matrix layer 310 on the display substrate 100 surrounds a light-emitting region 50 and has the same shape as the surrounded light-emitting region 50.

For example, referring to FIG. 17C, the shape of the first light-emitting region 51 of the first sub-pixel P1 and the shape of the second light-emitting region 52 of the second sub-pixel P2 are each substantially a circular shape, and the shape of the third light-emitting region 53 of the third sub-pixel P3 is substantially a quasi-ellipse.

The boundary of the first light-emitting region 51 is tangent to the first reference region 61. The boundary of the second light-emitting region 52 is substantially tangent to the boundary of the second reference region 62. The third light-emitting region 53 is located within the third reference region 63.

The orthogonal projection of the opening 30 of the black matrix layer 310 on the display substrate 100 surrounds a reference region 60 and has the same shape as the surrounded reference region 60.

For example, referring to FIG. 18C, in the display panel shown in FIG. 18C and the display panel shown in FIG. 17C, the display substrates 100 may have the same structure and the touch layers 200 may have the same structure, which will not be repeated here. As shown in FIG. 18C, the orthogonal projection of the opening 30 of the black matrix layer 310 on the display substrate 100 surrounds a light-emitting region 50 and has the same shape as the surrounded light-emitting region 50.

For example, referring to FIG. 17D, the first light-emitting region 51 of the first sub-pixel P1 and the second light-emitting region 52 of the second sub-pixel P2 are each in a shape of a rhombus, and the third light-emitting region 53 of the third sub-pixel P3 is in a shape of a diamond.

The boundary of the first light-emitting region 51 substantially coincides with the boundary of the first reference region 61. The boundary of the second light-emitting region 52 substantially coincides with the boundary of the second reference region 62. Borders of the third light-emitting region 53, which are formed by the first straight edge 504, the second straight edge 505, the first straight line segment 516 and the second straight line segment 536 of a diamond, coincide with part of the boundary of the third reference region 63 (two third virtual straight edges 632 and two fourth virtual straight edges 633), and a border of the third light-emitting region 53 formed by the third curved edge 506 of a diamond is located within the third reference region 63.

The orthogonal projection of the opening 30 of the black matrix layer 310 on the display substrate 100 surrounds a reference region 60 and has the same shape as the surrounded reference region 60.

For example, referring to FIG. 18D, in the display panel shown in FIG. 18D and the display panel shown in FIG. 17D, the display substrates 100 may have the same structure and the touch layers 200 may have the same structure, which will not be repeated here. As shown in FIG. 18D, the orthogonal projection of the opening 30 of the black matrix layer 310 on the display substrate 100 surrounds a light-emitting region 50 and has the same shape as the surrounded light-emitting region 50.

For example, referring to FIG. 17E, the first light-emitting region 51 of the first sub-pixel P1 and the third light-emitting region 53 of the third sub-pixel P3 are each in a shape of a rhombus, and the second light-emitting region 52 of the second sub-pixel P2 is in a shape of a diamond.

The boundary of the first light-emitting region 51 substantially coincides with the boundary of the first reference region 61. Borders of the second light-emitting region 52, which are formed by the first straight edge 504, the second straight edge 505, the first straight line segment 516 and the second straight line segment 536 of a diamond, coincide with two second virtual straight edges 621; and a border of the second light-emitting region 52 formed by the curved line segment 526 of a diamond is located within the second reference region 62.

Borders of the third light-emitting region 53, which are formed by the first straight edge 504, the second straight edge 505, the first straight line segment 516 and the second straight line segment 536 of a diamond, coincide with two second virtual straight edges 621; and a border of the third light-emitting region 53 formed by the curved line segment 526 of a diamond is located within the third reference region 63. Part of the boundary of the third light-emitting region 53 coincides with two third virtual straight edges 632 and two fourth virtual straight edges 633, and part of the boundary of the third light-emitting region 53 is located within the third reference region 63.

The orthogonal projection of the opening 30 of the black matrix layer 310 on the display substrate 100 surrounds a reference region 60 and has the same shape as the surrounded reference region 60.

For example, referring to FIG. 18E, in the display panel shown in FIG. 18E and the display panel shown in FIG. 17E, the display substrates 100 may have the same structure and the touch layers 200 may have the same structure, which will not be repeated here. As shown in FIG. 18E, the orthogonal projection of the opening 30 of the black matrix layer 310 on the display substrate 100 surrounds a light-emitting region 50 and has the same shape as the surrounded light-emitting region 50.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the scope of the present disclosure shall be subject to the protection scope of the claims.

1. A display panel, comprising:
a display substrate including a plurality of sub-pixels, wherein each sub-pixel has a light-emitting region, the light-emitting region is located within a reference region, an area of the light-emitting region is less than or equal to an area of the reference region; a shape of the reference region is a closed figure enclosed by at least one straight edge and at least one arc edge;
a touch layer located on a light-exit side of the display substrate, wherein the touch layer includes a metal mesh structure, and the metal mesh structure includes a plurality of metal lines; orthogonal projections of the plurality of metal lines on the display substrate are located between reference regions where light-emitting regions of the plurality of sub-pixels are located; and a spacing exists between a metal line adjacent to the light-emitting region of the sub-pixel and the reference region where the light-emitting region is located; and
a black matrix layer located on a side of the touch layer away from the display substrate and including a plurality of openings, wherein an orthogonal projection of each opening on the display substrate surrounds a single light-emitting region and is at least partially located outside a reference region where the single light-emitting region is located.

2. The display panel according to claim 1, wherein the plurality of sub-pixels include a plurality of first sub-pixels, each first sub-pixel has a first light-emitting region, and each first light-emitting region is located within a first reference region; the plurality of openings include a plurality of first openings, an orthogonal projection of each first opening on the display substrate surrounds a single first light-emitting region, and a shape of the first opening is the same as a shape of the first light-emitting region surrounded by the first opening.

3. The display panel according to claim 1, wherein the plurality of sub-pixels include a plurality of first sub-pixels, each first sub-pixel has a first light-emitting region, and each first light-emitting region is located within a first reference region; the plurality of openings include a plurality of first openings, and an orthogonal projection of each first opening on the display substrate surrounds a single first reference region; a boundary of the first opening and a boundary of a first light-emitting region surrounded by the first opening have a spacing therebetween, and a shape of the first opening is the same as a shape of the first reference region surrounded by the first opening.

4. The display panel according to claim 3, wherein the first opening is substantially in a shape of a rhombus and includes four first borders connected end to end, and the first borders are substantially straight lines; a diagonal line of the first opening extends substantially in a first direction, and another diagonal line of the first opening extends substantially in a second direction; the first direction is a row direction in which the plurality of sub-pixels are arranged, and the second direction is a column direction in which the plurality of sub-pixels are arranged.

5. The display panel according to claim 4, wherein the metal mesh structure includes a plurality of first meshes, a first mesh is substantially in a shape of a hexagon and includes two first extension sections that are oppositely arranged and extend in the first direction and four second extension sections; and the four second extension sections are substantially parallel to the four first borders, respectively;
an orthogonal projection of each first mesh on the display substrate surrounds an orthogonal projection of a first opening on the display substrate.

6. (canceled)

7. (canceled)

8. The display panel according to claim 2, wherein
the shape of the first light-emitting region is substantially a circle, and a boundary of the first light-emitting region has a distance from the first reference region, or is tangent to the first reference region; or
the shape of the first light-emitting region is substantially a rhombus, and the boundary of the first light-emitting region substantially coincides with a boundary of the first reference region.

9. The display panel according to claim 1, wherein the plurality of sub-pixels include a plurality of second sub-pixels, each second sub-pixel has a second light-emitting region, and each second light-emitting region is located within a second reference region; the plurality of openings include a plurality of second openings, an orthogonal projection of each second opening on the display substrate surrounds a single second light-emitting region, and a shape of the second opening is the same as a shape of the second light-emitting region surrounded by the second opening.

10. The display panel according to claim 1, wherein the plurality of sub-pixels include a plurality of second sub-pixels, each second sub-pixel has a second light-emitting region, and each second light-emitting region is located within a second reference region; the plurality of openings include a plurality of second openings, and an orthogonal projection of each second opening on the display substrate surrounds a single second reference region; a boundary of the second opening and a boundary of a second light-emitting region surrounded by the second opening have a spacing therebetween, and a shape of the second opening is the same as a shape of the second reference region surrounded by the second opening.

11. The display panel according to claim 10, wherein the second opening is substantially in a shape of a rhombus and includes four second borders connected end to end, and the second borders are substantially straight lines; a diagonal line of the second opening extends substantially in a first direction, and another diagonal line of the second opening extends substantially in a second direction; the first direction is a row direction in which the plurality of sub-pixels are arranged, and the second direction is a column direction in which the plurality of sub-pixels are arranged;
the plurality of sub-pixels further include a plurality of first sub-pixels each having a first light-emitting region, the plurality of openings include a plurality of first openings, and an area of the second light-emitting region is greater than an area of a first light-emitting region, and an area of the second opening is greater than an area of a first opening.

12. The display panel according to claim 11, wherein
the metal mesh structure further includes a plurality of second meshes, an orthogonal projection of each second mesh on the display substrate surrounds a single second opening, and the second mesh includes four third extension sections; and the four third extension sections are substantially parallel to the four second borders, respectively.

13. The display panel according to claim 12, wherein the black matrix layer further includes a plurality of light-transmitting holes; two sides of the second opening in a first direction are each provided with one light-transmitting hole, and the light-transmitting hole is located between two adjacent first openings in a second direction;
an orthogonal projection of the second mesh on the display substrate further surrounds orthogonal projections, on the display substrate, of two light-transmitting holes on the two sides of the second opening in the first direction; the second mesh further includes four fourth extension sections extending in the first direction and two fifth extension sections extending in the second direction; each two fourth extension sections constitute a group and are respectively located on two sides of a light-transmitting hole in the second direction; an end of a fourth extension section close to the second opening is connected to a single third extension section; and a fifth extension section is connected to two ends, away from the second opening, of two fourth extension sections in a group.

14. (canceled)

15. The display panel according to claim 9, wherein the shape of the second light-emitting region is substantially a circle, a quasi-ellipse, a rhombus or a diamond, wherein
the quasi-ellipse includes a first curved edge and a second curved edge, two ends of the first curved edge are respectively connected to two ends of the second curved edge, and a line connecting two connection points of the first curved edge and the second curved edge is a first line segment; the first curved edge and the first line segment enclose a semi-ellipse, and the second curved edge and the first line segment enclose a semicircle;
the diamond includes a first straight edge, a second straight edge and a third curved edge, the first straight edge and the second straight edge are connected to form a first polyline-shaped edge, and two ends of the third curved edge are respectively connected to two ends of the first polyline-shaped edge; the third curved edge includes a first straight line segment, a curved line segment and a second straight line segment connected in sequence; and the first straight line segment is connected to the first straight edge, and the second straight line segment is connected to the second straight edge.

16. The display panel according to claim 15, wherein
in a case where the shape of the second light-emitting region is substantially a circle, a boundary of the second light-emitting region has a distance from the second reference region, or is tangent to the second reference region;
in a case where the shape of the second light-emitting region is substantially a quasi-ellipse, a border of the second light-emitting region formed by the first curved edge has a distance from the second reference region, and a border of the second light-emitting region formed by the second edge is tangent to the boundary of the second reference region;
in a case where the shape of the second light-emitting region is substantially a rhombus, the boundary of the second light-emitting region substantially coincides with the boundary of the second reference region;
in a case where the shape of the second light-emitting region is substantially a diamond, borders of the second light-emitting region formed by the first straight edge, the second straight edge, and the first straight line segment and the second straight line segment of the third curved edge coincide with part of the boundary of the second reference region, and a border of the second light-emitting region formed by the curved line segment of the third curved edge has a distance from the boundary of the second reference region.

17. The display panel according to claim 1, wherein the plurality of sub-pixels include a plurality of third sub-pixels, a third sub-pixel has a third light-emitting region, and each third light-emitting region is located in a third reference region; the plurality of openings include a plurality of third openings, an orthogonal projection of each third opening on the display substrate surrounds a single third light-emitting region, and a shape of the third opening is the same as a shape of the third light-emitting region surrounded by the third opening.

18. The display panel according to claim 1, wherein the plurality of sub-pixels include a plurality of third sub-pixels, a third sub-pixel has a third light-emitting region, and each third light-emitting region is located in a third reference region; the plurality of openings include a plurality of third openings, and an orthogonal projection of each third opening on the display substrate surrounds a single third reference region; a boundary of the third opening and a boundary of a third light-emitting region surrounded by the third opening have a spacing therebetween, and a shape of the third opening is the same as a shape of the third reference region surrounded by the third opening.

19. The display panel according to claim 18, wherein the third opening includes one arc border, two third borders and two fourth borders; the two third borders and the two fourth borders are substantially straight lines; two ends of the arc border are each connected to an end of a single third border; another end of the third border is connected to a single fourth border; another ends of the two fourth borders are connected to each other; the third opening has a first symmetry axis, and the first symmetry axis passes through a midpoint of the arc border and a connection point of the two fourth borders.

20. The display panel according to claim 17, wherein
the metal mesh structure further includes a plurality of third meshes; the third meshes are substantially hexagonal, and each include two sixth extension sections, two seventh extension sections and two eighth extension sections; and an orthogonal projection of each third mesh on the display substrate surrounds a single third opening.

21. (canceled)

22. (canceled)

23. The display panel according to claim 17, wherein
the metal mesh structure further includes a plurality of fourth meshes; a fourth mesh includes two polyline-shaped extension sections that are oppositely arranged and two ninth extension sections extending in a second direction; a polyline-shaped extension section includes three V-shaped sub-sections that are spaced apart in a first direction and two straight sub-sections that are each connected to two adjacent V-shaped sub-sections; V-shaped sub-sections of the two polyline-shaped extension sections protrude in directions away from each other; a ninth extension section connects ends of the two polyline-shaped extension sections;
an orthogonal projection of each fourth mesh on the display substrate surrounds orthogonal projections, on the display substrate, of two adjacent third openings in the first direction and one second opening located between the two third openings.

24-31. (canceled)

32. The display panel according to claim 1, wherein a spacing between an orthogonal projection of a boundary of the opening on the display substrate and a boundary of a reference region surrounded by the opening is D1; a spacing between the orthogonal projection of the boundary of the opening on the display substrate and a boundary of an orthogonal projection of a metal line on the display substrate is D2; a line width of the metal line is D3; a spacing between boundaries of light-emitting regions of two adjacent sub-pixels is D4; and
D3=D4−2×D1−2×D2.

33. (canceled)

34. (canceled)

35. A display apparatus, comprising the display panel according to any claim 1.
